(19) United States
(12) Patent Application Publication
(10) Pub. No.: US 2019/0203338 A1
(43) Pub. Date: Jul. 4, 2019

(54) VAPOR DEPOSITION MASK, FRAME-EQUIPPED VAPOR DEPOSITION MASK, METHOD FOR PRODUCING ORGANIC SEMICONDUCTOR ELEMENT, AND METHOD FOR PRODUCING ORGANIC EL DISPLAY

(71) Applicant: Dai Nippon Printing Co. Ltd., Tokyo (JP)

(72) Inventors: Hiroshi KAWASAKI, Tokyo (JP); Toshihiko TAKEDA, Tokyo (JP)

(73) Assignee: Dai Nippon Printing Co. Ltd., Tokyo (JP)

(21) Appl. No.: 16/302,302

(22) PCT Filed: May 23, 2017
(86) PCT No.: PCT/JP2017/019130

§ 371 Date: Nov. 16, 2018

(30) Foreign Application Priority Data
May 26, 2016 (JP) 2016-105178

(51) Int. Cl. C23C 14/04; C23C 14/24; H01L 51/50; H05B 33/10; H01L 51/00

(52) U.S. Cl. CPC C23C 14/042; C23C 14/24; H01L 51/0011; H05B 33/10; H01L 51/5012

(57) ABSTRACT

There is provided a vapor deposition mask including: a resin mask including a plurality of resin mask openings corresponding to a pattern to be produced by vapor deposition; and a metal mask including a metal mask opening, the resin mask and the metal mask being stacked such that the resin mask openings overlap with the metal mask opening, wherein the metal mask includes one or a plurality of rigidity adjustment parts that partially reduce rigidity of the metal mask at a position not overlapping with the resin mask openings of the resin mask.

### TECHNICAL FIELD

Embodiments of the present disclosure relate to a vapor deposition mask, a frame-equipped vapor deposition mask, a method for producing an organic semiconductor element, and a method for producing an organic EL display.

### BACKGROUND ART

Formation of a vapor deposition pattern using a vapor deposition mask is typically performed by bringing the vapor deposition mask in which openings corresponding to a pattern to be produced by vapor deposition are provided into close contact with a vapor deposition target, and causing a vapor deposition material released from a vapor deposition source to adhere onto the vapor deposition target through the openings.

As the aforementioned vapor deposition mask used for forming the vapor deposition pattern, for example, there is known a vapor deposition mask including: a resin mask including resin mask openings corresponding to a pattern to be produced by vapor deposition; and a metal mask including a metal mask opening (sometimes referred to as slit), the resin mask and the metal mask being stacked (for example, refer to Patent Document 1).

### CITATION LIST

### Patent Document

### Patent Document 1: Japanese Patent No. 5288072

### Patent Document 2: Japanese Patent Laid-Open No. 2014-125671

### SUMMARY

### Technical Problem

A primary object of an embodiment of the present disclosure is to provide, for a vapor deposition mask in which a resin mask and a metal mask are stacked and a frame-equipped vapor deposition mask in which the vapor deposition mask is fixed to a frame, a vapor deposition mask and a frame-equipped vapor deposition mask capable of forming a vapor deposition pattern with further higher definition, and moreover, to provide a method for producing an organic semiconductor element capable of producing an organic semiconductor element with excellent precision and a method for producing an organic EL display capable of producing an organic EL display with excellent precision.

### Solution to Problem

There is provided a vapor deposition mask of an embodiment of the present disclosure, including: a resin mask including a plurality of resin mask openings corresponding to a pattern to be produced by vapor deposition; and a metal mask including a metal mask opening, the resin mask and the metal mask being stacked such that the resin mask openings overlap with the metal mask opening, wherein the metal mask includes one or a plurality of rigidity adjustment parts that partially reduce rigidity of the metal mask at a position not overlapping with the resin mask openings of the resin mask.

Moreover, the rigidity adjustment part may be a through hole penetrating the metal mask or a recess part provided in the metal mask.

Moreover, when an area of a metal mask effective region as the metal mask that is assumed not to include the rigidity adjustment part is seen from the metal mask side in plan view is 100%, a total area of an opening region of the rigidity adjustment part as the vapor deposition mask is seen from the metal mask side in plan view may be not less than about 3%.

Moreover, an opening area of one rigidity adjustment part may be smaller than an opening area of one metal mask opening. Moreover, an opening width of one rigidity adjustment part may be smaller than an opening width of one metal mask opening.

Moreover, the rigidity adjustment part may be positioned so as to enclose the metal mask opening as the vapor deposition mask is seen from the metal mask side in plan view.

Moreover, a plurality of the metal mask openings may be provided, and the rigidity adjustment part may be positioned between any adjacent pair of the metal mask openings as the vapor deposition mask is seen from the metal mask side in plan view.

Moreover, a thickness of the metal mask may be within a range not less than about 5 μm and not more than about 35 μm. Moreover, a sectional shape of the metal mask may be a shape including broadening toward a vapor deposition source side.

Moreover, a thickness of the resin mask may be within a range not less than about 3 μm and less than about 10 μm. Moreover, a sectional shape of the resin mask may be a shape including broadening toward a vapor deposition source side. Moreover, a sectional shape of the resin mask may be a curved shape convex outward.

Moreover, an opening space of the metal mask opening may be partitioned by a bridge.

Moreover, there is provided a vapor deposition mask of an embodiment of the present disclosure, including: a resin mask including a plurality of resin mask openings corresponding to a pattern to be produced by vapor deposition; and a metal mask including a metal mask opening, the resin mask and the metal mask being stacked such that the resin mask openings overlap with the metal mask opening, wherein the metal mask includes one or a plurality of rigidity adjustment parts which partially enhance rigidity of the metal mask at a position not overlapping with the resin mask openings of the resin mask, and the rigidity adjustment part is a metal reinforcement article provided on a surface, of the metal mask, that is not in contact with the resin mask.

Moreover, there is provided a frame-equipped vapor deposition mask of an embodiment of the present disclosure, in which the aforementioned vapor deposition mask is fixed to a frame. Moreover, a plurality of the vapor deposition masks may be fixed to the frame.

Moreover, there is provided a method for producing an organic semiconductor element of an embodiment of the present disclosure, including a vapor deposition pattern forming step of forming a vapor deposition pattern on a vapor deposition target using a vapor deposition mask, wherein the vapor deposition mask used in the vapor deposition pattern forming step is the aforementioned vapor deposition mask.

Moreover, according to an embodiment of the present disclosure, there is provided a method for producing an organic EL display, wherein the organic semiconductor element produced by the aforementioned producing method is used.

### Advantageous Effects

According to a vapor deposition mask and the frame-equipped vapor deposition mask according to the present disclosure, a vapor deposition pattern with high definition can be formed. Moreover, according to the method for producing an organic semiconductor element according to the present disclosure, an organic semiconductor element can be produced with excellent precision. Moreover, according to the method for producing an organic EL display according to the present disclosure, an organic EL display can be produced with excellent precision.

### BRIEF DESCRIPTION OF DRAWINGS

FIG. 1(a) is a schematic cross-sectional view exemplarily showing a vapor deposition mask according to an embodiment of the present disclosure, and FIG. 1(b) is an elevation view exemplarily showing a vapor deposition mask according to an embodiment of the present disclosure as seen from the metal mask side in plan view.

FIG. 2 is an elevation view exemplarily showing a vapor deposition mask according to an embodiment of the present disclosure as seen from the metal mask side in plan view.

FIG. 3 is an elevation view exemplarily showing a vapor deposition mask according to an embodiment of the present disclosure as seen from the metal mask side in plan view.

FIG. 4 is an elevation view exemplarily showing a vapor deposition mask according to an embodiment of the present disclosure as seen from the metal mask side in plan view.

FIG. 5 shows expanded elevation views exemplarily showing a region designated by sign X in FIG. 1(b).

FIG. 6 exemplarily shows a schematic cross-sectional view taken along the line A-A in FIG. 5(a).

FIG. 7 exemplarily shows schematic cross-sectional views taken along the line A-A in FIG. 5(b).

FIG. 8 exemplarily shows schematic cross-sectional views taken along the line A-A in FIG. 5(c).

FIG. 9 shows expanded elevation views exemplarily showing the region designated by the sign X in FIG. 1(b).

FIG. 10 shows elevation views exemplarily showing a vapor deposition mask according to an embodiment of the present disclosure as seen from the metal mask side in plan view.

FIG. 11 shows elevation views exemplarily showing a vapor deposition mask according to an embodiment of the present disclosure as seen from the metal mask side in plan view.

FIG. 12 shows an elevation view exemplarily showing a vapor deposition mask according to an embodiment of the present disclosure as seen from the metal mask side in plan view.

FIG. 13 shows elevation views exemplarily showing a vapor deposition mask according to an embodiment of the present disclosure as seen from the metal mask side in plan view.

FIG. 14 is a schematic cross-sectional view exemplarily showing a metal mask constituting a vapor deposition mask according to another embodiment (i) of the present disclosure.

FIG. 15 is a schematic cross-sectional view exemplarily showing a metal mask constituting a vapor deposition mask according to another embodiment (ii) of the present disclosure.

FIG. 16 is a diagram showing a state where dimensions of gaps are categorized into levels.

FIG. 17 is an elevation view exemplarily showing a vapor deposition mask of Embodiment (A) as seen from the metal mask side in plan view.

FIG. 18 is an elevation view exemplarily showing a vapor deposition mask of Embodiment (A) as seen from the metal mask side in plan view.

FIG. 19 is an elevation view exemplarily showing a vapor deposition mask of Embodiment (A) as seen from the metal mask side in plan view.

FIGS. 20(a) and 20(b) are elevation views exemplarily showing vapor deposition masks of Embodiment (A) as seen from the metal mask side in plan view.

FIG. 21 is an elevation view exemplarily showing a vapor deposition mask of Embodiment (B) as seen from the metal mask side in plan view.

FIG. 22 is an elevation view exemplarily showing a vapor deposition mask of Embodiment (B) as seen from the metal mask side in plan view.

FIG. 23 is an elevation view exemplarily showing a frame-equipped vapor deposition mask.

FIG. 24 is an elevation view exemplarily showing a frame-equipped vapor deposition mask.

FIGS. 25(a) to 25(c) are elevation views exemplarily showing a frame.

FIG. 26 shows diagrams exemplarily showing rigidity adjustment parts.

FIG. 27 shows diagrams showing examples of devices including organic EL displays.

### DESCRIPTION OF EMBODIMENTS

Hereafter, embodiments of the present invention are described with reference to the drawings and the like. Notably, embodiments of the present invention can be implemented in many different modes and should not be construed to be limited to the contents of description of embodiments exemplified below. Moreover, while in the drawings, there are cases where widths, thicknesses, shapes of individual parts are schematically presented as compared with those in actual modes for more clarity of the description, they are merely exemplary, not limiting interpretation of an embodiment of the present invention. Moreover, in the specification of the present application and the drawings, elements similar to those described regarding already shown drawings are sometimes given the same signs to properly omit their detailed description. Moreover, while the description is made using terms such as “upward”, “downward” and the like for convenience of the description, the upward and downward directions may be reversed. The same holds true for the rightward and leftward directions.

«Vapor Deposition Mask»

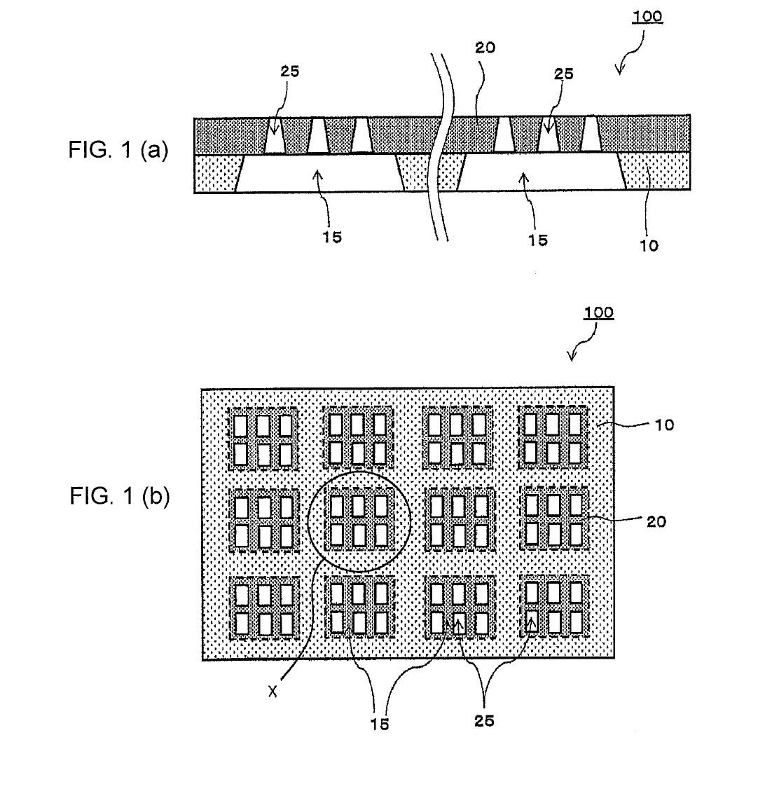

As shown in FIGS. 1(a) and 1(b), a vapor deposition mask 100 according to an embodiment of the present disclosure (hereinafter referred to as vapor deposition mask of the present disclosure) exhibits a configuration including: a resin mask 20 including a plurality of resin mask openings 25 corresponding to a pattern to be produced by vapor deposition; and a metal mask 10 including a metal mask opening 15, the resin mask and the metal mask being stacked such that the resin mask openings 25 overlap with the metal mask opening 15. Notably, FIG. 1(a) is a schematic cross-sectional view exemplarily showing the vapor deposition mask 100 of the present disclosure, FIG. 1(b) is an elevation view of the vapor deposition mask 100 of the present disclosure as seen from the metal mask side in plan view, and in the mode showing in FIG. 1, illustration of rigidity adjustment parts 35 mentioned later is omitted.

Formation of a vapor deposition pattern onto a vapor deposition target using the vapor deposition mask 100 exhibiting a stacking configuration in which the resin mask 20 and the metal mask 10 are stacked is performed by disposing the vapor deposition mask 100 on one surface side of the vapor deposition target, bringing the resin mask 20 of the vapor deposition mask 100 into close contact with the vapor deposition target, and after that, causing a vapor deposition material which is released from a vapor deposition source and has passed through vapor deposition mask openings 25 included in the resin mask 20 to adhere onto the vapor deposition target. Herein, when the resin mask 20 of the vapor deposition mask 100 is brought into close contact with the vapor deposition target, in the case where the close contact is low, in other words, in the case where a gap arises between the resin mask 20 of the vapor deposition mask 100 and the vapor deposition target, pieces of the vapor deposition pattern which have to be formed spaced at predetermined intervals are to result in their connection together with the vapor deposition material that comes around through the gap when the vapor deposition material released from the vapor deposition source has passed through the resin mask openings 25. Otherwise, there is to arise a problem that the dimension of the vapor deposition pattern thickens or the similar problem. Accordingly, in order to form a vapor deposition pattern with high definition, it is desirable that when the resin mask 20 of the vapor deposition mask 100 is brought into close contact with a vapor deposition target, the close contact be high, specifically, that the resin mask 20 of the vapor deposition mask 100 be brought into close contact with the vapor deposition target to such an extent that the aforementioned problem does not arise or that the problem can be sufficiently suppressed from arising.

As a method for improving close contact between the resin mask 20 of the vapor deposition mask 100 and a vapor deposition target, for example, a method of disposing a magnetic material on the other surface side of the vapor deposition target, and attracting the vapor deposition mask 100 and the vapor deposition target together using magnetic force of the magnetic material, a method of pressing the vapor deposition target from the other surface side of the vapor deposition target using a pressing member or the like, and pressing the vapor deposition target toward the vapor deposition mask 100 side, and the like can be cited.

Now, in order to sufficiently enhance close contact between the resin mask 20 of the vapor deposition mask 100 and the vapor deposition target, with stress exerted on the vapor deposition mask in the occasion of attracting the vapor deposition mask and the vapor deposition target together with magnetic force, or stress exerted on the vapor deposition mask in the occasion of pressing the vapor deposition target toward the vapor deposition mask side with the pressing member or the like (such stress is hereinafter sometimes referred to simply as stress or as stress exerted on a vapor deposition mask), it is needed to allow the shape of the resin mask 20 to deform so as to meet the shape of the vapor deposition target. For example, when a warp or the like arises on the vapor deposition mask 100, it is needed to allow the resin mask 20 to deform for cancelling the warp and making the vapor deposition mask 100 flat. Nevertheless, the metal mask 10 constituted of a metal material has higher rigidity as compared with the resin mask 20 constituted of a resin material, and the degree of deformation of the metal mask 10 in the occasion when stress or the like is exerted is smaller as compared with the degree of deformation of the resin mask 20. Further, since with the vapor deposition mask 100 configured by stacking the metal mask 10 and the resin mask 20, the degree of deformation of the metal mask 10 predominates the degree of deformation of the resin mask 20, if the metal mask 10 cannot be sufficiently allowed to deform, the shape of the resin mask 20 cannot be allowed to deform so as to meet the shape of the vapor deposition target even in the case of attracting the vapor deposition mask 100 and the vapor deposition target together or pressing the vapor deposition target toward the vapor deposition mask 100 side as mentioned above, and as a result, it is difficult to sufficiently enhance close contact between the resin mask 20 of the vapor deposition mask 100 and the vapor deposition target.

In particular, on a vapor deposition mask exhibiting a stacking configuration in which the resin mask 20 and the metal mask 10 with different thermal expansion coefficients are stacked, the difference between the thermal expansion coefficients tends to cause a warp (sometimes referred to as curl) or the like to arise on the vapor deposition mask 100, and if stress cannot be sufficiently allow the metal mask 10 to deform, it is difficult to sufficiently enhance close contact between the resin mask 20 of the vapor deposition mask 100 and the vapor deposition target.

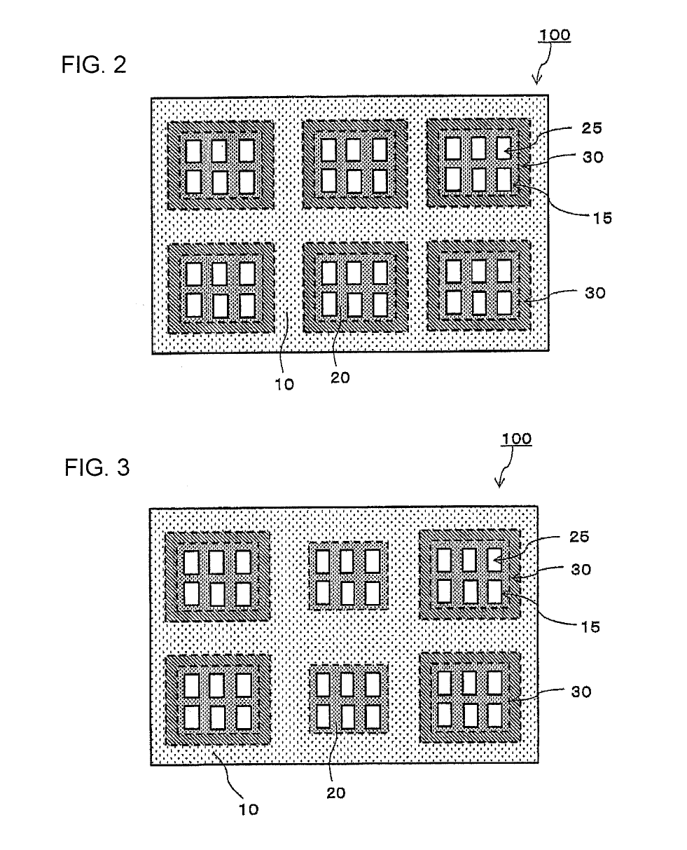

Therefore, as shown in FIG. 2 to FIG. 13, in the vapor deposition mask 100 of the present disclosure, the metal mask 10 includes one or a plurality of rigidity adjustment parts 35 that partially reduce rigidity of the metal mask 10 at a position not overlapping with the resin mask openings 25 of the resin mask 20. Notably, FIG. 2 to FIG. 4 and FIG. 10 to FIG. 13 show rigidity adjustment part arrangement regions 30 (each of which is hereinafter sometimes referred to as arrangement region) in each of which the rigidity adjustment part(s) 35 is (are) arranged. Notably, illustration of the rigidity adjustment parts 35 omitted from FIG. 2 to FIG. 4, one or a plurality of rigidity adjustment parts 35 are arranged in the arrangement region 30 in the figures.

According to the vapor deposition mask 100 of the present disclosure, by partially reducing the rigidity of the metal mask 10, softness (sometimes referred to as flexibility or elasticity) can be given to the metal mask 10, and the metal mask 10 can be easily allowed to deform with stress or the like. Accordingly, according to the vapor deposition mask 100 of the present disclosure, by partially reducing the rigidity of the metal mask 10, the shape of the resin mask 20 can be allowed to deform so as to meet the shape of the vapor deposition target using various methods when the resin mask 20 of the vapor deposition mask 100 is brought into close contact with the vapor deposition target. In other words, close contact between the resin mask 20 of the vapor deposition mask 100 and the vapor deposition target can be improved, and a vapor deposition pattern with high definition can be formed. FIG. 2 to FIG. 4 and FIG. 10 to FIG. 13 are plan views exemplarily showing the vapor deposition mask 100 of the present disclosure as seen from the metal mask 10 side in plan view. Hereafter, individual configurations of the vapor deposition mask 100 of the present disclosure are exemplarily described.

<Resin Mask>

As shown in FIG. 1(b), a plurality of resin mask openings 25 are provided in the resin mask 20. While in the mode shown in the figure, the opening shape of the resin mask opening 25 exhibits a rectangular shape, the opening shape of the resin mask opening 25 is not specially limited but may be any shape as long as it is a shape corresponding to a pattern to be produced by vapor deposition. For example, the opening shape of the resin mask opening 25 may be rhombic or polygonal or may be a shape having a curvature such as a circle and an ellipsoid. Notably, it can be said that the rectangular or polygonal opening shape is a preferable opening shape of the resin mask opening 25 in view of capability of securing a larger area of light emission as compared with the opening shape having a curvature such as a circle and an ellipsoid.

The material of the resin mask 20 is not limited but, for example, a material that enables formation of the resin mask openings 25 with high definition by laser processing or the like, includes a low rate of dimensional change and a low rate of humidity absorption under heat and with passage of time, and is light weight is preferably used. As such materials, a polyimide resin, a polyamide resin, a polyamide-imide resin, a polyester resin, a polyethylene resin, a polyvinyl alcohol resin, a polypropylene resin, a polycarbonate resin, a polystyrene resin, a polyacrylonitrile resin, an ethylene-vinyl acetate copolymer resin, an ethylene-vinyl alcohol copolymer resin, an ethylene-methacrylic acid copolymer resin, a polyvinyl chloride resin, a polyvinylidene chloride resin, cellophane, an ionomer resin and the like can be cited. Among the materials exemplarily cited above, resin materials with the thermal expansion coefficients of about 16 ppm/° C. or less are preferable, resin materials with the rates of humidity absorption of about 1.0% or less are preferable, and resin materials including both conditions are particularly preferable. The resin mask using these resin materials enables dimensional precision of the resin mask openings 25 to be improved and a rate of dimensional change and a rate of humidity absorption under heat and with passage of time to be small.

The thickness of the resin mask 20 is not specially limited but, in the case of further improving the effect of suppressing generation of a shadow, the thickness of the resin mask 20 is preferably not more than about 25 μm, still preferably less than about 10 μm. A preferable range of the lower limit value is not specially limited but, in the case where the thickness of the resin mask 20 is less than about 3 μm, defects such as a pinhole tend to arise and a risk of deformation or the like increases. In particular, by setting the thickness of the resin mask 20 to be not less than about 3 μm and less than about 10 μm, still preferably not less than about 4 μm and not more than about 8 μm, the influence of a shadow in formation of a high definition pattern exceeding 400 ppi can be more effectively prevented. Moreover, while the resin mask 20 may be directly bonded to the metal mask 10 mentioned later or may be bonded thereto via a pressure-sensitive adhesive agent layer, in the case where the resin mask 20 is bonded to the metal mask 10 via the pressure-sensitive adhesive agent layer, the total thickness of the resin mask 20 and the pressure-sensitive adhesive agent layer is preferably within the aforementioned preferable thickness range. Notably, the shadow is a phenomenon that a part of a vapor deposition material released from a vapor deposition source collides with inner wall surfaces of the metal mask opening of the metal mask and/or the resin mask opening of the resin mask and does not reach the vapor deposition target, and thereby, a portion without vapor deposition that has a film thickness smaller than the intended vapor deposition film thickness arises.

The sectional shape of the resin mask opening 25 is not specially limited but end surfaces that face each other and are of the resin mask forming the resin mask openings 25 may be substantially parallel to each other, but as shown in FIG. 1(a), the sectional shape of the resin mask opening 25 is preferably a shape including broadening toward a vapor deposition source. In other words, it preferably includes a taper surface including broadening toward the metal mask 10 side. While a taper angle can be properly set with the thickness or the like of the resin mask 20 taken into consideration, an angle formed by a straight line connecting the lower bottom distal end in the resin mask opening of the resin mask and the upper bottom distal end of the resin mask opening of the same resin mask and the bottom surface of the resin mask, in other words, an angle formed by an inner wall surface of the resin mask opening 25 and a surface of the resin mask 20 on the side that is not in contact with the metal mask 10 (upper surface of the resin mask in the mode shown in the figure) in the thicknesswise cross section of the inner wall surface constituting the resin mask opening 25 of the resin mask 20 is preferably within a range not less than about 5° and not more than about 85°, still preferably within a range not less than about 15° and not more than about 75°, further preferably within a range not less than about 25° and not more than about 65°. In particular, within this range, it is preferably an angle smaller than a vapor deposition angle of a vapor deposition machine to be used. Moreover, in the mode shown in the figure, while an end surface that forms the resin mask opening 25 exhibits a linear shape, there is no limitation thereto but may be in a curved shape convex outward, in other words, a shape of the entirety of the resin mask opening 25 may be a bowl shape.

<Metal Mask>

As shown in FIG. 1(a), the metal mask 10 is stacked on one surface of the resin mask 20. The metal mask 10 is constituted of metal, in which the metal mask openings 15 extending in the lengthwise direction or the crosswise direction are arranged as shown in FIG. 1(b). An arrangement example of the metal mask opening 15 is not specially limited but the metal mask opening 15 extending in the lengthwise direction and the crosswise direction may be arranged in a plurality of rows in the lengthwise direction and the crosswise direction, the metal mask opening 15 extending in the lengthwise direction may be arranged in a plurality of rows in the crosswise direction, and the metal mask openings extending in the crosswise direction may be arranged in a plurality of rows in the lengthwise direction. Moreover, they may be arranged in only one row in the lengthwise direction or the crosswise direction. Moreover, the plurality of metal mask openings 15 may be arranged at random. Moreover, one metal mask opening 15 may be provided. Notably, “lengthwise direction” and “crosswise direction” stated in the specification of the present application indicate the vertical direction and the horizontal direction in the drawings, respectively, and may be any directions of the longitudinal directions and the width directions of the vapor deposition mask, the resin mask and the metal mask. For example, the longitudinal direction of the vapor deposition mask, the resin mask or the metal mask may be set to be the “lengthwise direction”, or the width direction thereof may be set to be the “lengthwise direction”. Moreover, while in the specification of the present application, the case where the shape of the vapor deposition mask in plan view is a rectangular shape is exemplarily described, it may be another shape such, for example, as a circular shape and a polygonal shape such as a rhombic shape. In this case, the longitudinal direction of the diagonal line, the radial direction, or any direction only has to be set as the “longitudinal direction”, the direction perpendicular to the “longitudinal direction” being set as the “width direction (sometimes referred to as short-side direction)”.

(Rigidity Adjustment Part)

As shown in FIG. 2 to FIG. 13, the metal mask 10 includes one or a plurality of rigidity adjustment parts 35 that partially reduce rigidity of the metal mask 10 at a position not overlapping with the resin mask openings 25 of the resin mask 20. Specifically, in each of the arrangement regions 30 shown in FIG. 2 to FIG. 4 and FIG. 10 to FIG. 13, one or a plurality of rigidity adjustment parts 35 for partially reducing rigidity of the metal mask 10 are positioned.

Notably, the rigidity of a metal mask stated in the specification of the present application means the degree of ease of deformation of the metal mask (sometimes referred to as displacement or displacement amount) in a region on which certain load is exerted when the load is exerted on the vapor deposition mask, and the rigidity of the metal mask decreases more as the rigidity becomes lower, in other words, as the displacement amount becomes larger. The rigidity of the metal mask can be calculated by the following expression (1). Specifically, rigidity (k) of the metal mask can be calculated by exerting normal load (F) on a predetermined region of the vapor deposition mask 100, and measuring a displacement amount (δ) of the metal mask in the region on which the normal load (F) is exerted. Measurement of the displacement amount (δ) of the metal mask can be performed, for example, using a laser displacement meter or the like. Moreover, as a method of exerting the normal load, for example, a method of placing a weight with a predetermined mass in a predetermined region, a device of exerting load, or the like can be used.

k=F/δ (1)

With the vapor deposition mask 100 of the present disclosure, by positioning the rigidity adjustment part 35 in the arrangement region 30, the rigidity of the metal mask 10 in the arrangement region 30 can be reduced more than the rigidity in a region in which the rigidity adjustment part 35 is not arranged. In other words, by setting the metal mask 10 to include the rigidity adjustment part 35, softness can be given to the metal mask. According to the vapor deposition mask 100 of the present disclosure, softness given to the metal mask 10 can allow the shape of the resin mask 20 to deform to such an extent that a gap does not arise between it and the vapor deposition target, when the vapor deposition mask 100 is brought into close contact with the vapor deposition target using stress such that the resin mask 20 opposes the vapor deposition target. In other words, the shape of the resin mask 20 can be caused to meet the shape of the vapor deposition target. In other words, close contact between the vapor deposition mask 100 and the vapor deposition target can be improved.

A method of partially reducing rigidity of the metal mask 10 by the rigidity adjustment part 35 is not specially limited but can be realized by various methods as exemplarily presented below. Moreover, the rigidity of a metal mask can also be partially reduced by methods other than those.

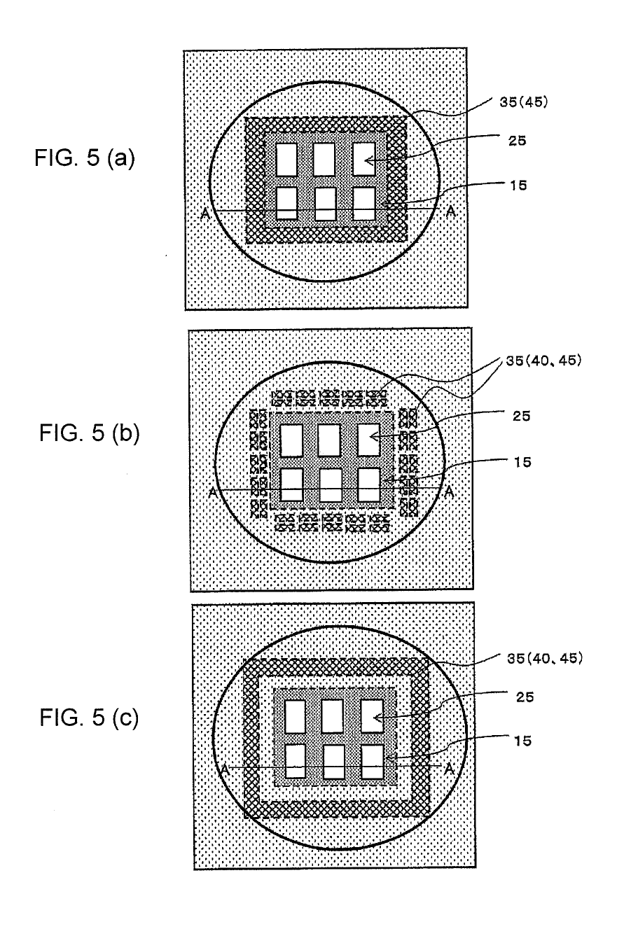

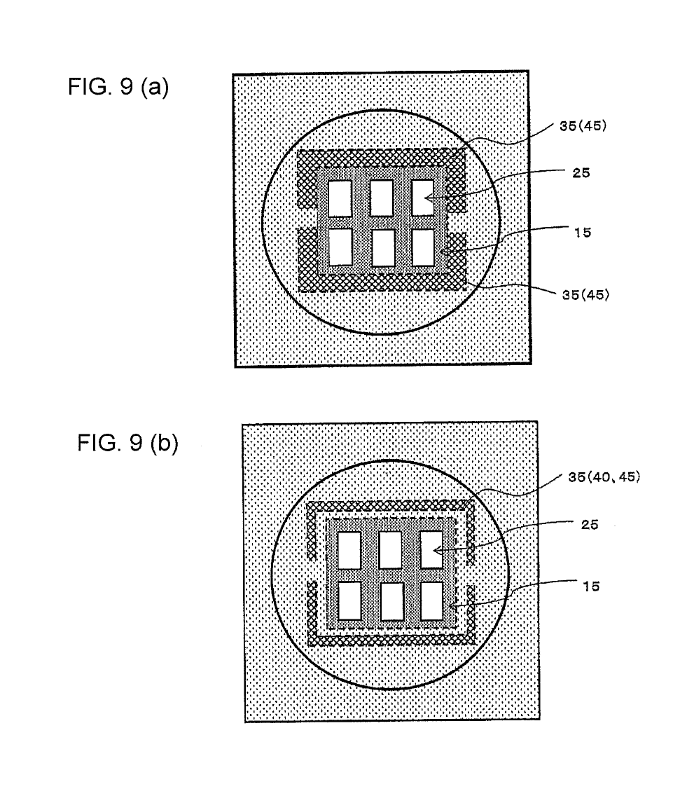

(i) For example, by providing one or a plurality of through holes 40 penetrating the metal mask 10 as the rigidity adjustment parts 35 in a predetermined region of the metal mask not overlapping with the resin mask openings 25 in the thicknesswise direction, in other words, in a region whose rigidity is desired to be reduced, the rigidity of the metal mask 10 in a peripheral region including the through holes 40 can be reduced (refer to FIGS. 5(b) and 5(c) and FIG. 9(b)).

The through hole 40 stated here means a hole penetrating only the metal mask 10. A method of forming the through hole 40 is not specially limited but etching, cutting or the like can be properly selected and performed.

(ii) Moreover, by providing one or a plurality of recess parts 45 not penetrating the metal mask 10 as the rigidity adjustment parts 35 in a predetermined region of the metal mask not overlapping with the resin mask openings 25 in the thicknesswise direction, in other words, in a region whose rigidity is desired to be reduced, the rigidity of the metal mask 10 in a peripheral region including the recess parts 45 can also be reduced (refer to FIG. 5 and FIG. 9).

A method of forming the recess part 45 is not specially limited but etching, cutting or the like can be properly selected and performed. The depth of the recess part 45 is not specially limited but can be properly set with the thickness of the metal mask 10 and the degree of reduction of rigidity taken into consideration. By way of example, it is within a range not less than about 1 μm and not more than about 100 μm.

Hereafter, unless otherwise noted, when the rigidity adjustment parts 35 are stated, they are supposed to include the through holes 40 and the recess parts 45 as the rigidity adjustment parts 35.

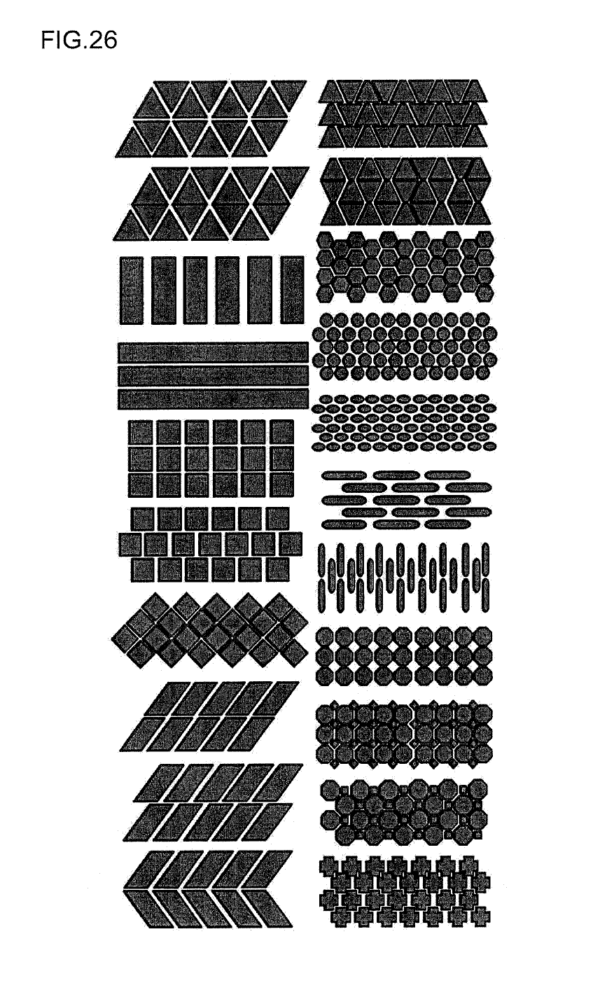

The shape of the through hole 40 or the recess part 45 as the rigidity adjustment part 35 is not specially limited but, for example, as a shape thereof as the vapor deposition mask 100 is seen from the metal mask 10 side in plan view, polygonal shapes such as a triangle, a rectangle, a rhombus, a trapezoid, a pentagon and a hexagon, a circular shape, an ellipsoid shape, shapes with curvatures at corners of polygons, and the like can be cited. Moreover, it can also be a shape obtained by combining these. FIG. 26 shows diagrams exemplarily showing aggregates of “rigidity adjustment parts” as seen from the metal mask 10 side in plan view. Notably, in FIG. 26, a closed region may be set to be the rigidity adjustment part 35, or such a closed region can also be set to be a non-through hole or a non-recess part.

The dimension of the through hole 40 or the recess part 45 as the rigidity adjustment part 35 is not specially limited but only has to be properly set depending on a place where the rigidity adjustment part 35 is positioned. For example, the area of the opening region of the rigidity adjustment part 35 as seen from the metal mask side in plan view may be made larger or smaller than or the same as the area of the opening region of the metal mask opening 15. Notably, with easiness in adjusting the rigidity of the metal mask 10 taken into consideration, the area of the opening region of one rigidity adjustment part 35 is preferably made smaller than the area of the opening region of the metal mask opening 15. By way of example, the area of the opening region of one rigidity adjustment part 35, in other words, the area of the opening region of one through hole 40 or one recess part 45 is within a range not less than about 1 μm² and not more than about 1×10¹² μm².

The opening width of the through hole 40 or the recess part 45 as the rigidity adjustment part 35 is not specially limited but, for example, the opening widths of the rigidity adjustment part 35 in the longitudinal direction and the width direction of the vapor deposition mask as seen from the metal mask side in plan view may be made larger or smaller than or the same widths as the opening widths of the metal mask opening 15 in the longitudinal direction and the width direction of the vapor deposition mask. Notably, the opening width of the rigidity adjustment part 35 only has to be properly set depending on a place where the through hole 40 is positioned and, for example, when the metal mask 10 includes a plurality of metal mask openings 15 and the rigidity adjustment part 35 is positioned between the adjacent metal mask openings 15 in the longitudinal direction of the vapor deposition mask, the opening width of the rigidity adjustment part 35 in the longitudinal direction as seen from the metal mask 10 side in plan view only has to be made smaller than the distance between the adjacent metal mask openings 15 in the longitudinal direction. The same holds true for the case where the rigidity adjustment part 35 is positioned between the adjacent metal mask openings 15 in the width direction of the vapor deposition mask.

Moreover, when the area of a metal mask effective region as the metal mask that is assumed not to include the rigidity adjustment part(s) 35, in other words, the metal mask only including the metal mask openings 15 is seen from the metal mask side in plan view is 100%, the total area of the opening region(s) of the through hole(s) 40 or the recess part(s) 45 as the rigidity adjustment part(s) 35 as the vapor deposition mask 100 of the present disclosure is seen from the metal mask 10 side in plan view is preferably not less than about 3%, preferably not less than about 10%, particularly preferably not less than about 30%. Notably, the area of the metal mask effective region stated here means the surface area of the portion where metal portions exist as the vapor deposition mask is seen from the metal mask 10 side in plan view. By setting the ratio of the area of the opening region(s) of the through hole(s) 40 or the recess part(s) 45 as the rigidity adjustment part(s) 35 to be within the aforementioned preferable range, softness can be given to the metal mask 10 while the rigidity of the metal mask 10 as a whole is being sufficiently held, and close contact between the resin mask 20 of the vapor deposition mask 100 and the vapor deposition target can be further improved. The upper limit value of the total area of the opening region(s) of the rigidity adjustment part(s) 35 is not specially limited but with the rigidity of the metal mask taken into consideration, it is preferably not more than about 95%, still preferably not more than about 90%, particularly preferably not more than about 70%.

Arrangement positions and pitches of the rigidity adjustment parts 35, in other words, the through holes 40 or the recess parts 45 as the rigidity adjustment parts described above are not specially limited but they may be regularly arranged or may be arranged at random. Moreover, as an example of the pitch between the adjacent rigidity adjustment parts 35, a range not less than about 1 μm and not more than about 2×10⁶ μm can be cited.

Moreover, when a plurality of rigidity adjustment parts 35 are provided in the metal mask 10, the areas of the opening regions of the individual rigidity adjustment parts 35 may be the same as one another or may be different from one another. The same holds true for the pitches thereof. Moreover, the through hole 40 and the recess part 45 as the rigidity adjustment part 35 can also be combined and used.

(Rigidity Adjustment Part Arrangement Region)

An arrangement region in which the rigidity adjustment part 35 is arranged is not specially limited but it only has to be properly arranged at a place where the rigidity of the metal mask 10 is desired to be reduced, in other words, at a position where close contact between the resin mask 20 and the vapor deposition target tends to be insufficient. As shown in FIG. 2 to FIG. 4 and FIG. 10 to FIG. 13, on the metal mask 10 in a preferable mode, the arrangement region 30 is positioned in the periphery of the metal mask opening 15, and in the arrangement region 30, one or a plurality of rigidity adjustment parts 35 are arranged. According to the vapor deposition mask 100 of the present disclosure including the metal mask 10 in a preferable mode, close contact between the resin mask 20 of the vapor deposition mask 100 and the vapor deposition target can be set to be extremely excellent, and a vapor deposition pattern with further higher definition can be formed.

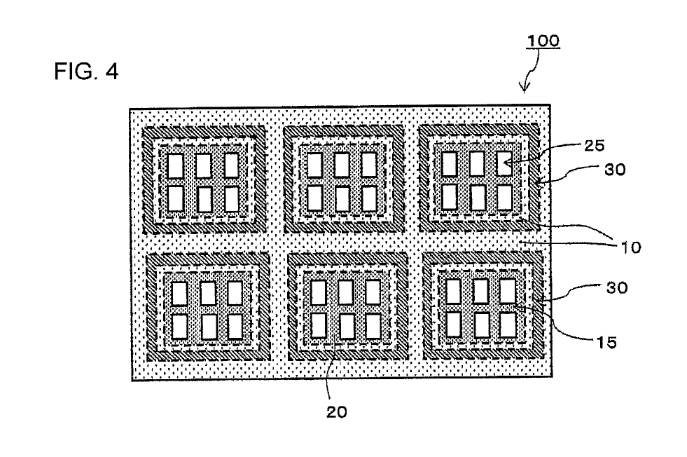

In the vapor deposition masks 100 in the modes shown in FIG. 2 and FIG. 3, the metal mask 10 includes a plurality of metal mask openings 15, and the arrangement region 30 is positioned so as to enclose the metal mask opening 15. Notably, in the mode shown in FIG. 2, the arrangement region 30 is positioned such that it encloses the metal mask opening 15 and the outer edge of the metal mask opening 15 overlaps with an outer edge of the arrangement region 30. Moreover, in the mode shown in FIG. 3, the arrangement region 30 is positioned such that it encloses at least one metal mask opening 15 of the plurality of metal mask openings 15 and the outer edge of the metal mask opening 15 overlaps with an outer edge of the arrangement region 30. Moreover, in the mode shown in FIG. 4, the arrangement region 30 is positioned such that it encloses the metal mask opening 15 and the outer edge of the metal mask opening 15 does not overlap with the outer edge of the arrangement region 30, in other words, it is spaced at a predetermined distance from the outer edge of the metal mask opening 15.

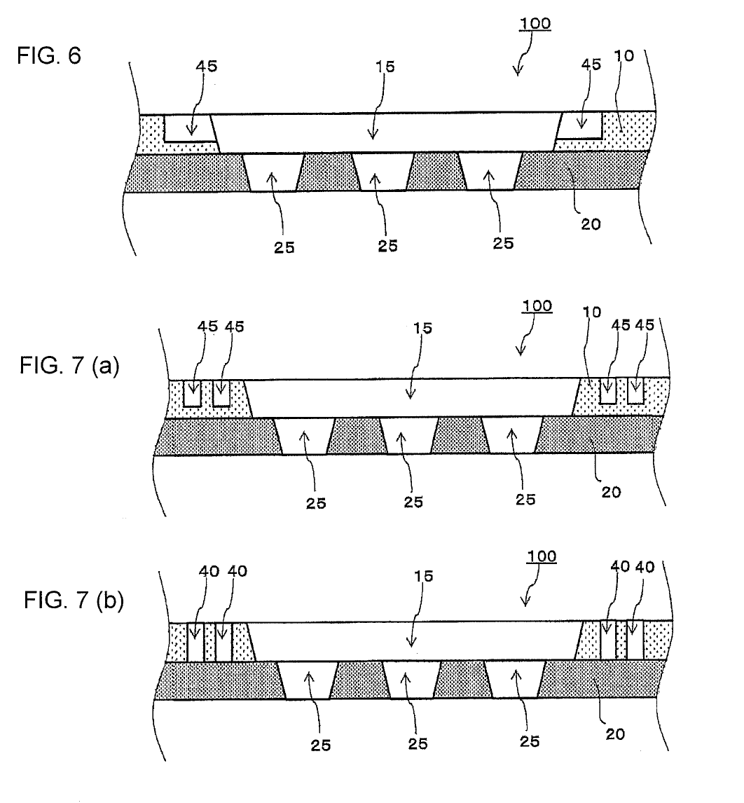

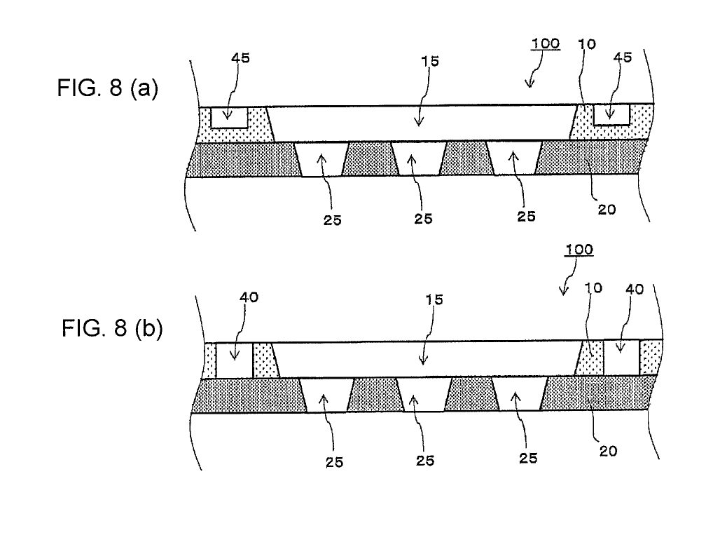

FIG. 5 and FIG. 9 are expanded elevation views (expanded elevation views exemplarily showing the region designated by sign X in FIG. 1(b)) exemplarily showing arrangements of the rigidity adjustment part(s) 35 arranged in the arrangement region 30, FIG. 6 exemplarily shows a schematic cross-sectional view taken along the line A-A in FIG. 5(a), FIGS. 7(a) and 7(b) exemplarily show schematic cross-sectional views taken along the line A-A in FIG. 5(b), and FIGS. 8(a) and 8(b) exemplarily show schematic cross-sectional views taken along the line A-A in FIG. 5(c). In the mode shown in FIG. 5(a), the recess part 45 as one continuous rigidity adjustment part 35 encloses one metal mask opening 15 such that the outer edge of the metal mask opening 15 overlaps with an outer edge of the rigidity adjustment part 35. Moreover, in the mode shown in FIG. 5(b), an aggregate of a plurality of rigidity adjustment parts 35 encloses one metal mask opening 15 such that the outer edge of metal mask opening 15 does not overlap with the outer edges of the rigidity adjustment parts 35. The rigidity adjustment part 35 in the mode shown in FIG. 5(b) may be any of the through hole 40 and the recess part 45. Moreover, in the mode shown in FIG. 5(c), one continuous rigidity adjustment part 35 encloses one metal mask opening 15 such that the outer edge of the metal mask opening 15 does not overlap with the outer edge of the rigidity adjustment part 35. The rigidity adjustment part 35 shown in FIG. 5(c) may be one continuous through hole 40 or one continuous recess part 45. Moreover, a configuration obtained by combining these modes may be employed.

The vapor deposition mask 100 in a preferable mode is in modes of enclosing the metal mask opening 15 with one or a plurality of rigidity adjustment parts 35 such that the outer edge of the metal mask opening 15 does not overlap with the outer edge of the arrangement region 30, in other words, such that the outer edge of the metal mask opening 15 does not overlap with the outer edge(s) of the rigidity adjustment part(s) 35 (modes shown in FIGS. 5(b) and 5(c)). According to the vapor deposition mask 100 in a preferable mode, when disposing a magnetic material on the other surface side of the vapor deposition target and attracting the vapor deposition mask 100 and the vapor deposition target together using magnetic force of the magnetic material, close contact between the vapor deposition mask 100 and the vapor deposition target at a position overlapping with the outer circumferential end part of the metal mask opening 15 can be more improved.

Moreover, the rigidity adjustment part 35 shown in each figure can also be divided into a plurality of rigidity adjustment parts 35. FIG. 9(a) shows a mode in which one rigidity adjustment part 35 shown in FIG. 5(a) is divided into a plurality of rigidity adjustment parts 35, and FIG. 9(b) shows a mode in which one rigidity adjustment part 35 shown in FIG. 5(c) is divided into a plurality of rigidity adjustment parts 35. Moreover, the modes shown in the figures can also be properly combined.

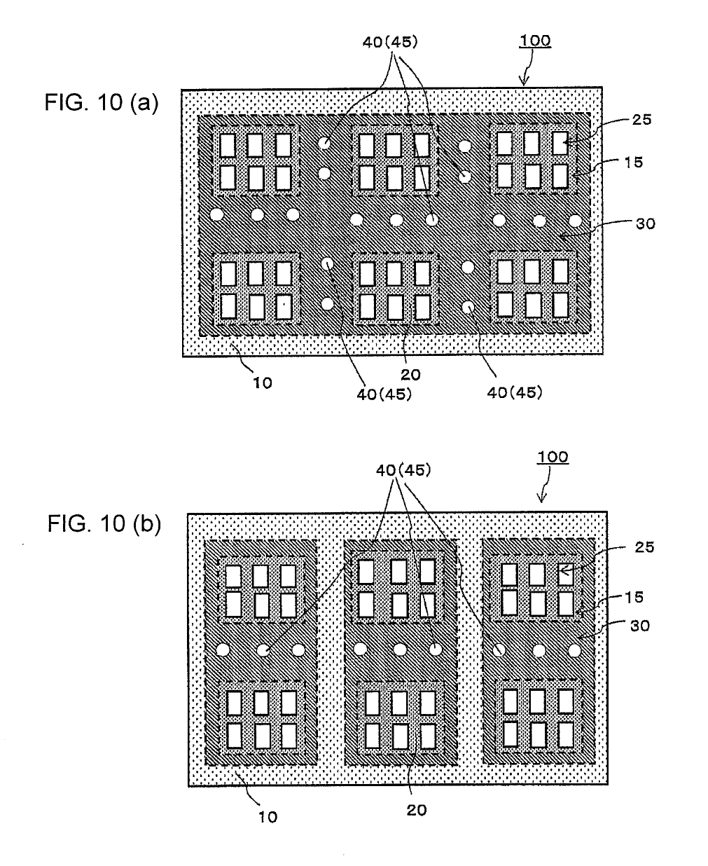

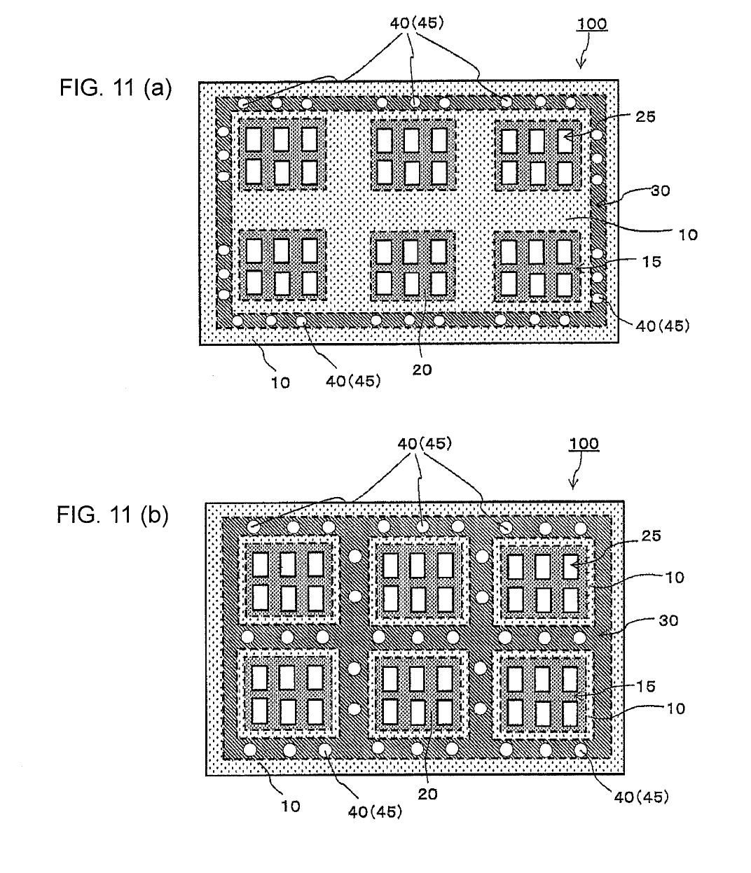

In the vapor deposition masks 100 in the modes shown in FIGS. 10(a) and 10(b) and FIGS. 11(a) and 11(b), the metal mask 10 includes a plurality of metal mask openings 15, and the arrangement region 30 is positioned so as to collectively enclose the plurality of metal mask openings 15. Notably, in the mode shown in FIG. 10, the outer edges of the metal mask openings 15 overlap with outer edges of the arrangement region 30, and in the mode shown in FIG. 11, the outer edges of the arrangement region 30 are positioned to be spaced at predetermined distances from the outer edges of the metal mask openings 15. While in the modes shown in FIG. 10 and FIG. 11, a plurality of rigidity adjustment parts 35 are arranged in the arrangement region 30, the whole arrangement region 30 may be set to be the recess part 45 in the mode shown in FIG. 10, Moreover, in the mode shown in FIG. 11, the whole arrangement region 30 may be set to be the through hole 40 or the recess part 45.

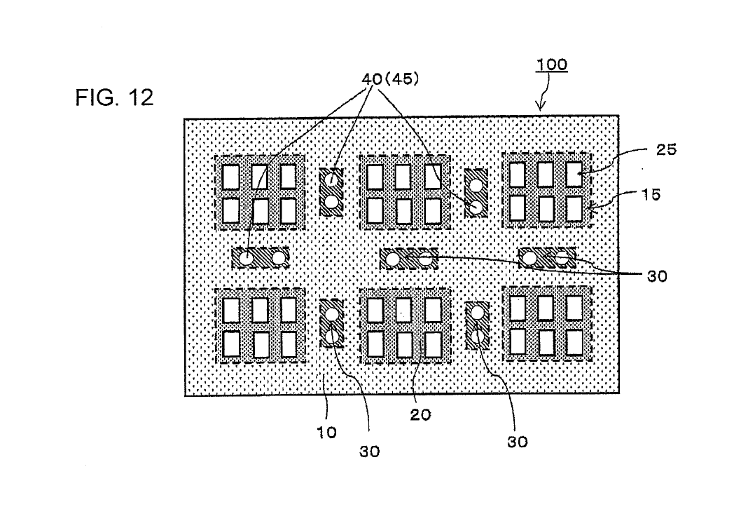

In the vapor deposition mask 100 in the mode shown in FIG. 12, the metal mask 10 includes a plurality of metal mask openings 15, and the arrangement regions 30 are positioned between at least part of adjacent pairs of the metal mask openings 15. While in the mode shown in FIG. 12, a plurality of rigidity adjustment parts 35 are arranged in the arrangement region 30, the whole arrangement region 30 may be the through hole 40 or the recess part 45 in the mode shown in FIG. 12.

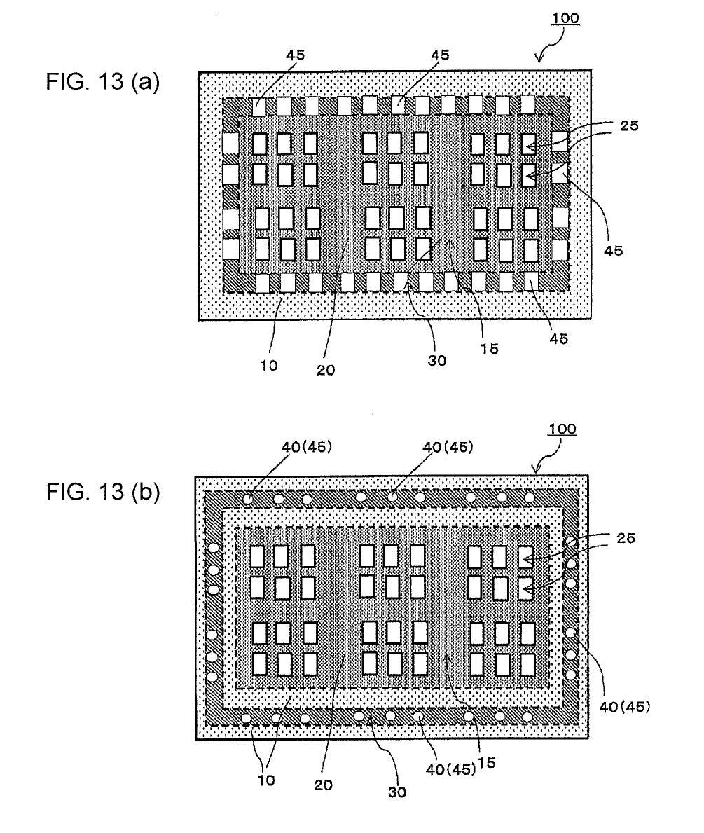

In the vapor deposition mask 100 in the modes shown in FIGS. 13(a) and 13(b), the metal mask 10 only includes one metal mask opening 15, and the arrangement region 30 is positioned so as to enclose the one metal mask opening 15. Notably, in the mode shown in FIG. 13(a), the outer edge of the metal mask opening 15 overlaps with the outer edge of the arrangement region 30, and in the mode shown in FIG. 13(b), the outer edge of the arrangement region 30 is positioned to be spaced at a predetermined distance from the outer edge of the metal mask opening 15. Notably, since fixation of a vapor deposition mask to a frame is typically performed at the outer circumference of the vapor deposition mask, with this point taken into consideration, the outer edge of the metal mask 10 is preferable not to overlap with the outer edge of the arrangement region 30. In other words, the recess part 45 is preferable not to be positioned in a portion overlapping with the outer edge of the metal mask. While in the mode shown in FIG. 13, a plurality of rigidity adjustment parts 35 are arranged in the arrangement region 30, the whole arrangement region 30 may be set to be the recess part 45 in the mode shown in FIG. 13(a), and the whole arrangement region 30 may be set to be the through hole 40 or the recess part 45 in the mode shown in FIG. 13(b). In other words, the whole arrangement region may be set to be the rigidity adjustment part 35, in other words, one continuous through hole 40 or recess part 45 may enclose one metal mask opening 15 (refer to FIGS. 5(a) and 5(c)). Moreover, in place of the mode shown in the figure, the rigidity adjustment parts 35 may be arranged only in a part of the arrangement region 30 for example, only close to the corners of the metal mask (not shown).

On the vapor deposition mask 100 in a preferable mode, when the metal mask 10 only includes one metal mask opening 15, the arrangement region 30 is positioned at a position enclosing the one metal mask opening 15 and spaced at a predetermined distance from the outer edge of the metal mask opening 15, and the whole arrangement region is set to be one rigidity adjustment part 35 (not shown) or a plurality of rigidity adjustment parts 35 are arranged along the arrangement region 30 (not shown). According to the vapor deposition mask 100 in a preferable mode, when disposing a magnetic material on the other surface side of the vapor deposition target and attracting the vapor deposition mask 100 and the vapor deposition target together using magnetic force of the magnetic material, close contact between the vapor deposition mask 100 and the vapor deposition target at a position overlapping with the outer circumferential end part of the metal mask opening 15 can be more improved.

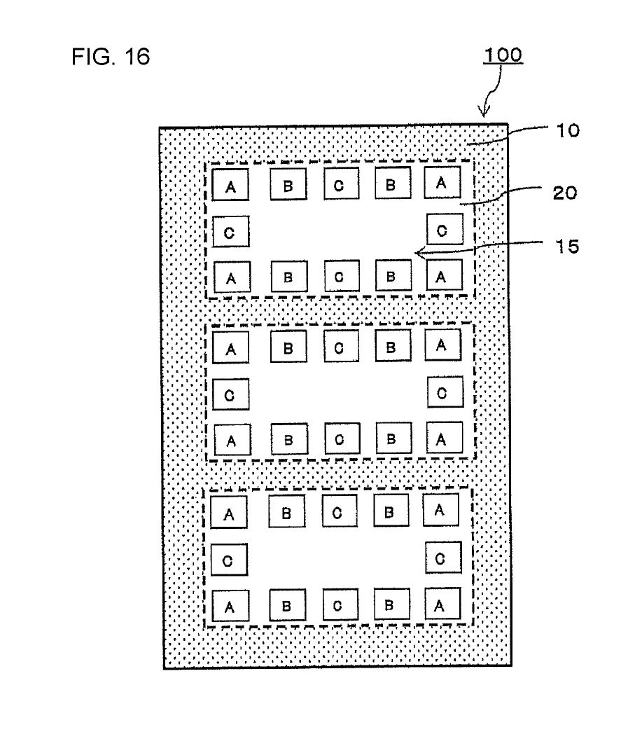

FIG. 16 is an elevation view showing a state where dimensions of gaps which can arise between the resin mask 20 of the vapor deposition mask 100 and the vapor deposition target and can arise when the metal mask 10 includes a plurality of metal mask openings 15 and the rigidity adjustment part 35 is not positioned in the metal mask 10 are categorized into levels, and there is a tendency that a gap more easily arises in the order of “C”>“B”>“A”.

Accordingly, on the vapor deposition mask 100 in a preferable mode, the rigidity adjustment parts 35 are preferably positioned in the peripheral regions of the metal mask openings 15 corresponding to places (at the level “C”) which are shown in FIG. 16 and are supposed for gaps to highly possibly arise, the rigidity adjustment parts 35 are still preferably positioned in the peripheral regions of the metal mask openings 15 corresponding to the level “C” and the level “B”, and the rigidity adjustment parts 35 are particularly preferably positioned in the peripheral regions of all the metal mask openings 15. Moreover, the areas of the opening regions of the rigidity adjustment parts 35, the ratios occupied by the rigidity adjustment parts, and the like can also be changed depending on the individual regions to change the rigidity of the metal mask 10 in stages. For example, when a peripheral region including the level “C” is set to be a first region, a peripheral region including the level “B” is set to be a second region, a peripheral region including the level “A” is set to be a third region, and the areas of the first region to the third region are set to be the same areas as one another, by changing the ratios of the rigidity adjustment parts 35 occupied in the individual regions, the rigidity of the metal mask can be adjusted for the individual regions. For example, by making the ratio of the rigidity adjustment part 35 occupied in the first region larger than the ratio of the rigidity adjustment part occupied in the second region, and in the third region, not positioning the rigidity adjustment part 35 or making the ratio of the rigidity adjustment part 35 occupied therein smaller than in the second region, the rigidity of the metal mask can be adjusted for the individual regions.

The material of the metal mask 10 is not specially limited but a conventionally known one in the field of the vapor deposition mask can be properly selected and used, and, for example, metal materials such as stainless steel, iron-nickel alloy and aluminum alloy can be cited. Above all, an invar material which is iron-nickel alloy can be preferably used since an invar material is hardly deformed by heat.

While the thickness of the metal mask 10 is not specially limited but, in order to more effectively prevent generation of a shadow, is preferably not more than about 100 μm, still preferably not more than about 50 μm, particularly preferably not more than about 35 μm. Notably, in the case of being thinner than about 5 μm, risks of rupture and deformation tend to increase and handling tends to be difficult.

Moreover, while in the mode shown in each figure, the shape of opening of the metal mask opening 15 in plan view exhibits a rectangular shape, the opening shape is not specially limited but the opening shape of the metal mask opening 15 may be any shape such as a trapezoid and a circle.

The sectional shape of the metal mask opening 15 formed in the metal mask 10 is not specially limited but, as shown in FIG. 1(a), is preferably a shape including broadening toward a vapor deposition source. More specifically, an angle formed by a straight line connecting the lower bottom distal end in the metal mask opening 15 of the metal mask 10 and the upper bottom distal end in the metal mask opening 15 of the same metal mask 10 and the bottom surface of the metal mask 10, in other words, an angle formed by an inner wall surface of the metal mask opening 15 and a surface of the metal mask 10 on the side that is in contact with the resin mask 20 (upper surface of the metal mask in the mode shown in the figure) in the thicknesswise cross section of the inner wall surface constituting the metal mask opening 15 of the metal mask 10 is preferably within a range not less than about 5° and not more than about 85°, still preferably within a range not less than about 15° and not more than about 80°, further preferably within a range not less than about 25° and not more than about 65°. In particular, within this range, it is preferably an angle smaller than a vapor deposition angle of a vapor deposition machine to be used.

Moreover, an opening space of the metal mask opening 15 may be partitioned by a bridge (not shown).

A method of stacking the metal mask 10 on the resin mask is not specially limited but the resin mask 20 and the metal mask 10 may be pasted together using various pressure-sensitive adhesive agents or a resin mask with self-adhesion may be used. The dimensions of the resin mask 20 and the metal mask 10 may be the same as or different from each other. Notably, with fixation to a frame which is arbitrarily performed after that taken into consideration, the dimension of the resin mask 20 is preferably made smaller than that of the metal mask 10 to realize the state where the outer circumferential portion of the metal mask 10 is exposed, so that the metal mask 10 can be easily fixed to a frame.

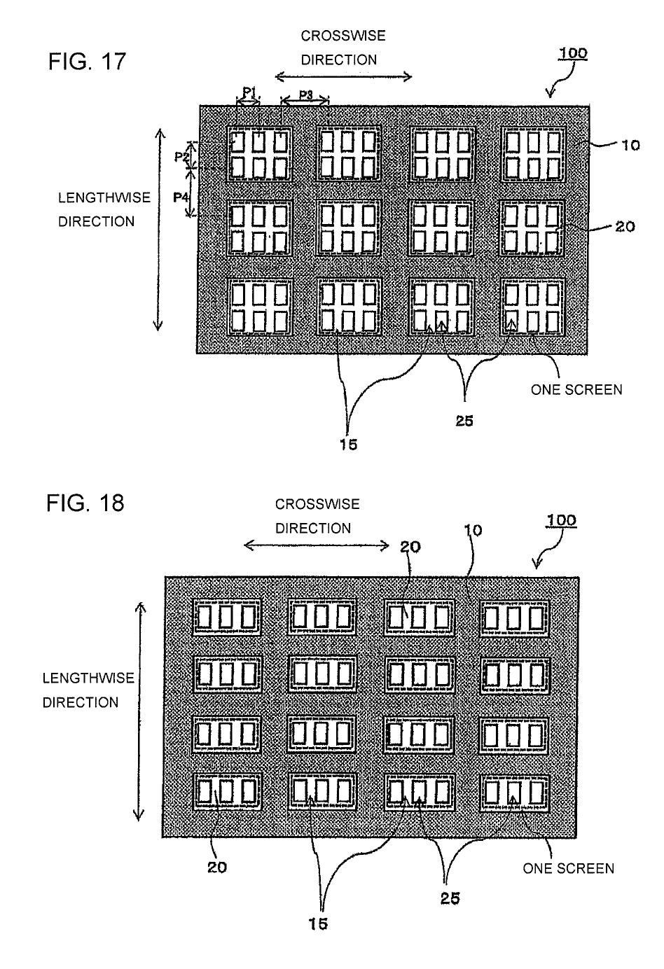

Next, more preferable examples of a vapor deposition mask of the present disclosure are specifically described, exemplified by Embodiment (A) and Embodiment (B). Notably, while in FIG. 17 to FIG. 22, illustration of the rigidity adjustment parts 35 and the arrangement regions 30 is omitted, the configurations described above can be properly applied to the rigidity adjustment parts 35 and the arrangement regions 30 therein.

<Vapor Deposition Mask of Embodiment (A)>

As shown in FIG. 17, the vapor deposition mask 100 of Embodiment (A) is a vapor deposition mask for simultaneously forming vapor deposition patterns for a plurality of screens, and includes the metal mask 10 in which the plurality of metal mask openings 15 are provided and the resin mask 20, the metal mask being stacked on one surface of the resin mask, wherein the resin mask openings 25 needed for constituting the plurality of screens are provided in the resin mask 20, and each metal mask opening 15 is provided at a position overlapping with the entirety of at least one screen. Furthermore, the metal mask 10 of the vapor deposition mask 100 of Embodiment (A) includes one or a plurality of rigidity adjustment parts 35 that partially reduce rigidity of the metal mask 10 at a position not overlapping with the resin mask openings 25 of the resin mask 20, and in this way, close contact between the resin mask 20 and the vapor deposition target in the occasion when the vapor deposition mask of Embodiment (A) is brought into close contact with the vapor deposition target is improved. In the metal mask 10 of the vapor deposition mask 100 of Embodiment (A), the rigidity adjustment part(s) 35 are preferably positioned between at least one pair of screens of the screens, at a position enclosing at least one screen, at a position collectively enclosing a plurality of screens, or at a position collectively enclosing all the screens.

The vapor deposition mask 100 of Embodiment (A) is a vapor deposition mask used for simultaneously forming vapor deposition patterns for a plurality of screens, and one vapor deposition mask 100 can simultaneously form vapor deposition patterns compatible with a plurality of products. “Resin mask openings” stated for the vapor deposition mask of Embodiment (A) mean the pattern(s) to be produced using the vapor deposition mask 100 of Embodiment (A). For example, when the vapor deposition mask is used for forming an organic layer in an organic EL display, the shape of the resin mask openings 25 is the shape of the organic layer. Moreover, “one screen” is constituted of an aggregate of the resin mask openings 25 corresponding to one product, and when the one product is an organic EL display, an aggregate of organic layers needed for forming the one organic EL display, in other words, an aggregate of resin mask openings 25 to be the organic layers is “one screen”. Further, in the vapor deposition mask 100 of Embodiment (A), in order to simultaneously form the vapor deposition patterns for the plurality of screens, the aforementioned “one screen” is arranged for each of the plurality of screens in the resin mask 20 at predetermined intervals. Namely, in the resin mask 20, the resin mask openings 25 needed for constituting the plurality of screens are provided.

The vapor deposition mask of Embodiment (A) includes the metal mask 10 in which the plurality of metal mask openings 15 are provided and the resin mask, the metal mask being provided on one surface of the resin mask, wherein each metal mask opening is provided at a position overlapping with the entirety of at least one screen. In other words, between the resin mask openings 25 needed for constituting one screen, metal line portions that include the same length as the length of the metal mask opening 15 in the lengthwise direction and include the same thickness as that of the metal mask 10 between the resin mask openings 25 adjacent in the crosswise direction, or metal line portions that include the same length as the length of the metal mask opening 15 in the crosswise direction and include the same thickness as that of the metal mask 10 between the resin mask openings 25 adjacent in the lengthwise direction do not exist. Hereafter, the metal line portions that include the same length as the length of the metal mask opening 15 in the lengthwise direction and include the same thickness as that of the metal mask 10 and the metal line portions that include the same length as the length of the metal mask opening 15 in the crosswise direction and include the same thickness as that of the metal mask 10 are sometimes collectively referred to simply as metal line portions.

According to the vapor deposition mask 100 of Embodiment (A), even when the dimension of the resin mask openings 25 needed for constituting one screen and the pitch between the resin mask openings 25 constituting one screen are made small, for example, even when the dimension of the resin mask openings 25 and the pitch between the resin mask openings 25 are made extremely fine in order to form a screen exceeding 400 ppi, interference due to metal line portions can be prevented and an image with high definition can be formed. Notably, when one screen is divided by a plurality of metal mask openings, in other words, when the metal line portions including the same thickness as that of the metal mask 10 exist between the resin mask openings 25 constituting one screen, as the pitch between the resin mask openings 25 constituting one screen becomes smaller, the metal line portions existing between the resin mask openings 25 more become a hindrance in forming a vapor deposition pattern on a vapor deposition target and the vapor deposition pattern with high definition becomes more difficult to be formed. In other words, when the metal line portions including the same thickness as that of the metal mask 10 exist between the resin mask openings 25 constituting one screen, the metal line portions cause generation of a shadow when setting the frame-equipped vapor deposition mask, which results in difficulty of formation of a screen with high definition.

Next, referring to FIG. 17 to FIG. 20, the resin mask openings 25 constituting one screen are exemplarily described. Notably, a region enclosed by a broken line in the modes shown in the figures is one screen. While in the modes shown in the figures, an aggregate of a small number of resin mask openings is one screen for convenience of description, but not limited to these modes, for example, the resin mask openings 25 for millions of pixels may exist in one screen, where one resin mask opening 25 is one pixel.

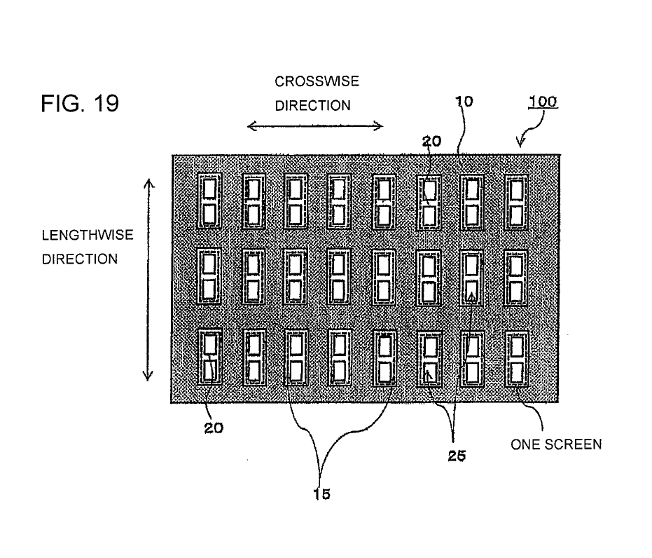

In the mode shown in FIG. 17, one screen is constituted of an aggregate, of resin mask openings 25, in which a plurality of resin mask openings 25 are provided in the lengthwise direction and the crosswise direction. In the mode shown in FIG. 18, one screen is constituted of an aggregate, of resin mask openings 25, in which a plurality of resin mask openings 25 are provided in the crosswise direction. Moreover, in the mode shown in FIG. 19, one screen is constituted of an aggregate, of resin mask openings 25, in which a plurality of resin mask openings 25 are provided in the lengthwise direction. Further, in FIG. 17 to FIG. 19, the metal mask opening 15 is provided at a position overlapping with the entirety of one screen.

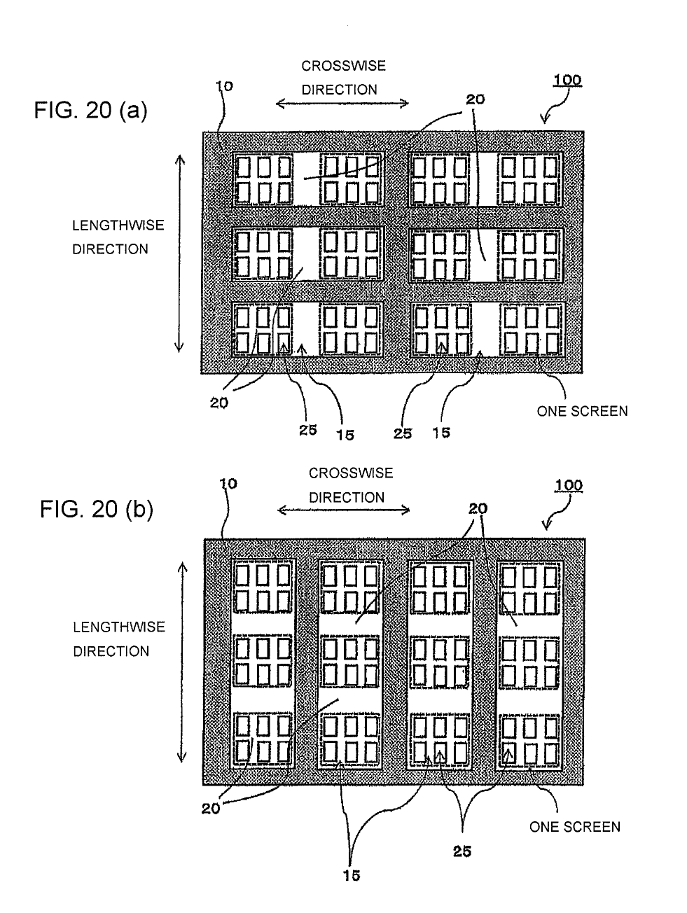

As described above, the metal mask opening 15 may be provided at a position overlapping with only one screen, or as shown in FIGS. 20(a) and 20(b), may be provided at a position overlapping with the entirety of two or more screens. In FIG. 20(a), in the resin mask 20 shown in FIG. 17, the metal mask opening 15 is provided at a position overlapping with the entirety of two screens continuous in the crosswise direction. In FIG. 20(b), the metal mask opening 15 is provided at a position overlapping with the entirety of three screens continuous in the lengthwise direction.

Next, exemplified by the mode shown in FIG. 17, pitches between the resin mask openings 25 constituting one screen and pitches between the screens are described. The pitches between the resin mask openings 25 constituting one screen and the dimension of the resin mask opening 25 are not specially limited but can be properly set depending on a pattern to be produced by vapor deposition. For example, when forming a vapor deposition pattern with high definition of 400 ppi, a pitch (P1) in the crosswise direction and a pitch (P2) in the lengthwise direction between the adjacent resin mask openings 25 out of the resin mask openings 25 constituting one screen are about 60 μm. Moreover, the dimension of the resin mask opening as one example is within a range not less than about 500 μm² and not more than about 1000 μm². Moreover, one resin mask opening 25 is not limited to correspond to one pixel but, for example, a plurality of pixels can also be collectively one resin mask opening 25 depending on a pixel arrangement.

While a pitch (P3) in the crosswise direction and a pitch (P4) in the lengthwise direction between the screens are not specially limited but, as shown in FIG. 17, when one metal mask opening 15 is provided at the position overlapping with the entirety of one screen, metal line portions are to exist between the screens. Accordingly, when the pitch (P4) in the lengthwise direction and the pitch (P3) in the crosswise direction between the screens are smaller than or substantially equal to the pitch (P2) in the lengthwise direction and the pitch (P1) in the crosswise direction of the resin mask openings 25 provided in one screen, the metal line portions existing between the screens are liable to break. In particular, when the rigidity adjustment part 35 is positioned between the screens, a risk of breakage of a metal line portion is high. Accordingly, with this point taken into consideration, the pitch (P3, P4) between the screens is preferably wider than the pitch (P1, P2) between the resin mask openings 25 constituting one screen. The pitch (P3, P4) between the screens is exemplarily within a range not less than about 1 mm and not more than about 100 mm. Notably, the pitch between the screens means the pitch between the adjacent resin mask openings in one screen and another screen adjacent to the one screen. The same holds true for the pitch between the resin mask openings 25 and the pitch between the screens in the vapor deposition mask of Embodiment (B) mentioned later.

Notably, as shown in FIG. 20, when one metal mask opening 15 is provided at the position overlapping with the entirety of two or more screens, metal line portions constituting the inner wall surfaces of the metal mask opening are not to exist between the plurality of screens provided in the one metal mask opening 15. Accordingly, in this case, the pitch between the two or more screens provided at the position overlapping with the one metal mask opening 15 may be substantially equal to the pitch between the resin mask openings 25 constituting one screen.

Moreover, on the resin mask 20, grooves (not shown) extending in the lengthwise direction or the crosswise direction of the resin mask 20 may be formed. While in the case of application of heat in vapor deposition, there is a possibility that the resin mask 20 undergoes thermal expansion, and thereby, changes in dimension and position of the resin mask opening 25 arise, by forming the grooves, they can absorb the expansion of the resin mask, and can prevent the changes in dimension and position of the resin mask opening 25 caused by the resin mask 20 expanding in a predetermined direction as a whole due to accumulation of thermal expansions arising in portions in the resin mask. Formation positions of the grooves are not limited but they may be provided between the resin mask openings 25 constituting one screen and at positions overlapping with the resin mask openings 25, but they are preferably provided between the screens. Moreover, the grooves may be provided on one surface of the resin mask, for example, only on the surface on the side that is in contact with the metal mask, or may be provided only on the surface on the side that is not in contact with the metal mask. Otherwise, they may be provided on both surfaces of the resin mask 20.

Moreover, the grooves extending in the lengthwise direction may be between the adjacent screens, or the grooves extending in the crosswise direction may be formed between the adjacent screens. Furthermore, the grooves can also be formed in a mode combining these.

The depth and the width of the grooves are not specially limited but, since the rigidity of the resin mask 20 tends to decrease in the case where the depth of the grooves is too large and in the case where the width thereof is too large, they are needed to be set with this point taken into consideration. Moreover, the sectional shape of the grooves is not specially limited but only has to be arbitrarily selected as a U-shape, a V-shape or the like with the processing method and the like taken into consideration. The same holds true for the vapor deposition mask of Embodiment (B).

<Vapor Deposition Mask of Embodiment (B)>

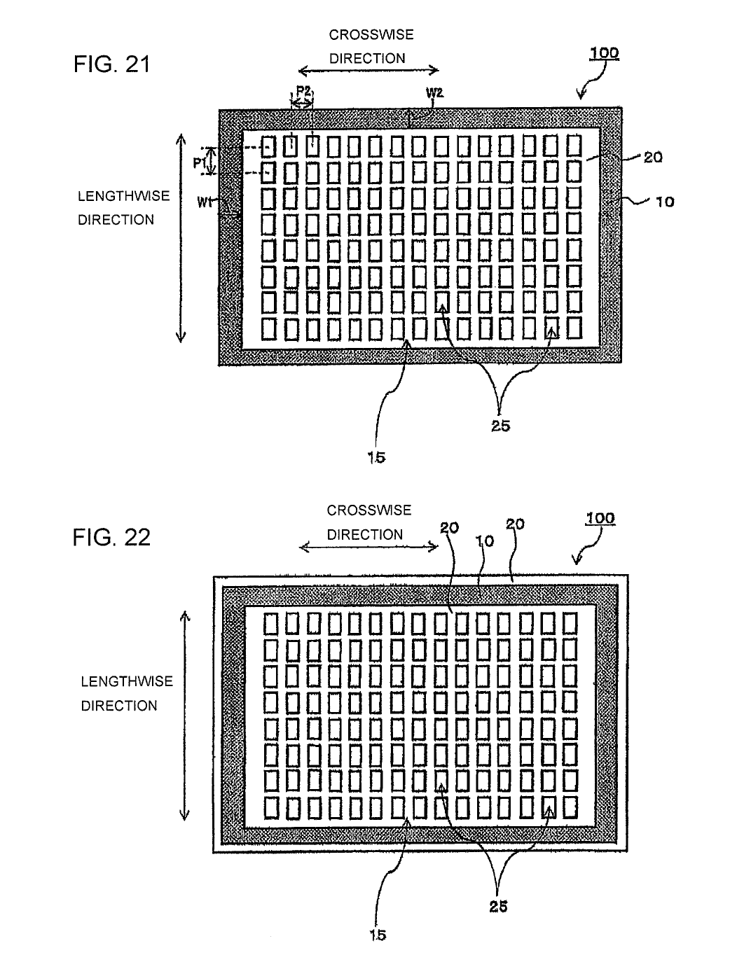

Next, a vapor deposition mask of Embodiment (B) is described. As shown in FIG. 21, a vapor deposition mask of Embodiment (B) includes the metal mask 10 in which one metal mask opening 15 is provided and the resin mask 20 in which the plurality of resin mask openings 25 corresponding to a pattern to be produced by vapor deposition are provided, the metal mask being stacked on one surface of the resin mask, wherein all of the plurality of resin mask openings 25 are provided at a position overlapping with the one metal mask opening 15 provided in the metal mask 10. Furthermore, the metal mask 10 of the vapor deposition mask 100 of Embodiment (B) includes one or a plurality of rigidity adjustment parts 35 that partially reduce rigidity of the metal mask 10 at a position not overlapping with the resin mask openings 25 of the resin mask 20, and in this way, close contact between the resin mask 20 and the vapor deposition target in the occasion when the vapor deposition mask of Embodiment (B) is brought into close contact with the vapor deposition target is improved. In the metal mask 10 of the vapor deposition mask 100 of Embodiment (B), the rigidity adjustment part(s) 35 are preferably positioned at a position enclosing one metal mask opening 15.

The resin mask openings 25 stated for the vapor deposition mask of Embodiment (B) mean resin mask openings needed for forming a vapor deposition pattern on a vapor deposition target, and resin mask openings not needed for forming the vapor deposition pattern on the vapor deposition target may be provided at a position not overlapping with the one metal mask opening 15. Notably, FIG. 21 is an elevation view which exemplarily shows the vapor deposition mask of Embodiment (B) and is of the vapor deposition mask as seen from the metal mask side in plan view.

In the vapor deposition mask 100 of Embodiment (B), the metal mask 10 including the one metal mask opening 15 is provided on the resin mask 20 including the plurality of resin mask openings 25, and all of the plurality of resin mask openings 25 are provided at a position overlapping with the one metal mask opening 15. In the vapor deposition mask 100 of Embodiment (B) with this configuration, metal line portions that include the same thickness as the thickness of the metal mask or a larger thickness than the thickness of the metal mask do not exist between the resin mask openings 25. Hence, as described for the aforementioned vapor deposition mask of Embodiment (A), a vapor deposition pattern with high definition can be formed to match the dimensions of the resin mask openings 25 provided in the resin mask 20 without suffering interference of metal line portions.

Moreover, according to the vapor deposition mask of Embodiment (B), there is almost no influence of a shadow even when the thickness of the metal mask 10 is made large. Hence, the thickness of the metal mask 10 can be made larger to such an extent that durability and handling ability are sufficiently satisfied. Durability and handling ability can be improved while enabling formation of a vapor deposition pattern with high definition.

The resin mask 20 in the vapor deposition mask of Embodiment (B) is constituted of resin, in which as shown in FIG. 21, the plurality of resin mask openings 25 corresponding to a pattern to be produced by vapor deposition are provided at a position overlapping with the one metal mask opening 15. The resin mask openings 25 correspond to the pattern to be produced by vapor deposition, and by a vapor deposition material which is released from a vapor deposition source passing through the resin mask openings 25, the vapor deposition pattern corresponding to the resin mask openings 25 is formed on the vapor deposition target. Notably, while in the mode shown in the figure, the resin mask openings arranged in a plurality of rows in the lengthwise direction and the crosswise direction are exemplarily described, they may be arranged only in the lengthwise direction or in the crosswise direction.

“One screen” in the vapor deposition mask 100 of Embodiment (B) means an aggregate of resin mask openings 25 corresponding to one product, and when the one product is an organic EL display, an aggregate of organic layers needed for forming one organic EL display, in other words, an aggregate of resin mask openings 25 to be the organic layers is “one screen”. While the vapor deposition mask of Embodiment (B) may be constituted of only “one screen” or may be provided by arranging the “one screen” for each of a plurality of screens, in the case where the “one screen” is arranged for each of the plurality of screens, the resin mask openings 25 are preferably provided at predetermined intervals on a screen-by-screen basis (refer to FIG. 17 for the vapor deposition mask of Embodiment (A)). The mode of “one screen” is not specially limited but, for example, the one screen can also be constituted of millions of resin mask openings 25, where one resin mask opening 25 is one pixel.

The metal mask 10 in the vapor deposition mask 100 of Embodiment (B) is constituted of metal and includes the one metal mask opening 15. Further, in the vapor deposition mask 100 of Embodiment (B), the one metal mask opening 15 is disposed at a position overlapping with all of the resin mask openings 25 as seen head-on of the metal mask 10, in other words, at a position where all of the resin mask openings 25 arranged in the resin mask 20 can be seen.

The metal portion constituting the metal mask 10, that is, the portion thereof other than the one metal mask opening 15 may be provided along the outer edge of the vapor deposition mask 100 as shown in FIG. 21, or the dimension of the metal mask 10 may be made smaller than that of the resin mask 20 to expose an outer circumferential portion of the resin mask 20 as shown in FIG. 22. Moreover, the dimension of the metal mask 10 may be made larger than that of the resin mask 20, so that a part of the metal portion is caused to protrude outward in the crosswise direction of the resin mask or outward in the lengthwise direction thereof. Notably, in any cases, the dimension of the one metal mask opening 15 is configured to be smaller than the dimension of the resin mask 20.

While a width (W1), in the crosswise direction, and a width (W2), in the lengthwise direction, of the metal portion constituting the wall surface of the one metal mask opening 15 of the metal mask 10 shown in FIG. 21 are not specially limited but, as the width W1, W2 is made smaller, durability and handling ability tend to deteriorate more. Accordingly, W1 and W2 are preferably widths by which durability and handling ability are sufficiently satisfied. While appropriate widths can be properly set depending on the thickness of the metal mask 10, as an example of preferable widths, both W1 and W2 are within a range of not less than about 1 mm and not more than about 100 mm, which are similar to those for the metal mask in the vapor deposition mask of Embodiment (A).

<Vapor Deposition Mask According to Another Embodiment (i)>

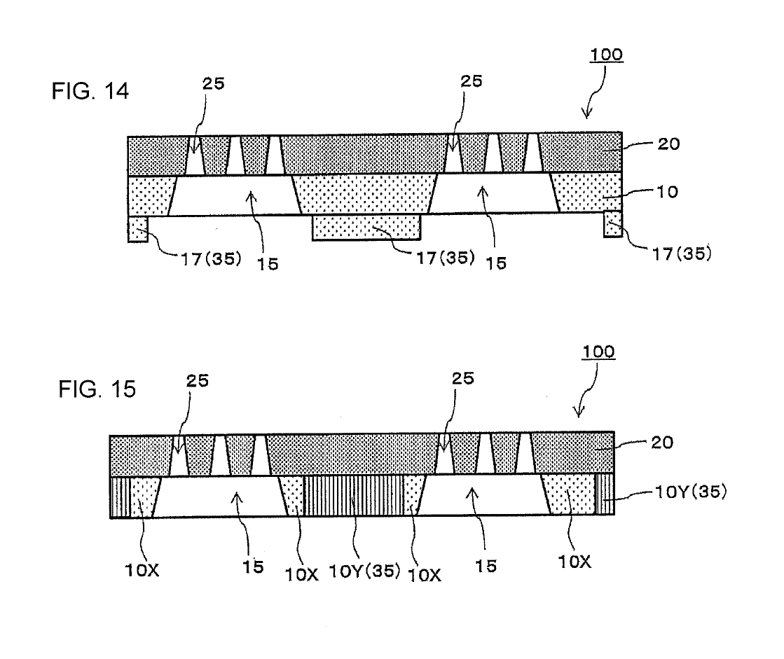

While in the vapor deposition masks according to the embodiments described above, the through hole 40 or the recess part 45 is provided as the rigidity adjustment part 35 in the metal mask 10, and in this way, the rigidity of the metal mask in a peripheral region including the through hole 40 or the recess part 45 is reduced, in place of these modes, as shown in FIG. 14, a metal reinforcement article 17 as the rigidity adjustment part 35 can also be provided on a surface, of the metal mask 10, that does not overlap with the resin mask openings 25 in the thicknesswise direction, and in this way, the rigidity of the metal mask 10 in a peripheral region including the metal reinforcement article can be enhanced.

In other words, while in the vapor deposition masks according to the embodiments described above, the rigidity of the metal mask in a peripheral region including the rigidity adjustment part is reduced by the through hole 40 or the recess part 45 as the rigidity adjustment part 35, the vapor deposition mask according to another embodiment (i) is different from the vapor deposition masks according to the embodiments described above in that the rigidity of the metal mask in a peripheral region including the rigidity adjustment part 35 is enhanced by the metal reinforcement article 17 as the rigidity adjustment part 35. Notably, unless otherwise noted, for the vapor deposition mask according to another embodiment (i), the configurations of the vapor deposition masks according to the embodiments described above can be properly selected and used.

The thickness of the metal mask 10 in the vapor deposition mask according to another embodiment (i) is not specially limited but only has to be a thickness to such an extent that it can give softness. By way of example, it is not more than about 35 μm, preferably not more than about 25 μm, still preferably not more than about 15 μm.

As the metal reinforcement article 17, for example, a metal plate provided on the metal mask 10, a metal plating layer formed on the metal mask, and the like can be cited.

An arrangement position of the metal reinforcement article is not specially limited but, for example, the metal reinforcement article 17 only has to be properly arranged in each of the regions shown by signs 10 in FIG. 2 to FIG. 4 and FIG. 10 to FIG. 13.

The thickness of the metal reinforcement article 17 is not specially limited but can be properly set depending on an extent to which the rigidity of the metal mask 10 is enhanced. By way of example, it is within a range not less than about 1 μm and not more than about 30 μm. Moreover, when a plurality of metal reinforcement articles 17 are arranged, the heights of the metal reinforcement articles 17 may be made different from one another to change the rigidity of the metal mask 10. Moreover, the materials of the metal reinforcement articles 17 may be made different from one another.

Moreover, in place of the metal reinforcement article 17, a reinforcement article including a material different from a metal material can also be used.

<Vapor Deposition Mask According to Another Embodiment (ii)>

Moreover, as shown in FIG. 15, combining one metal plate (10X) and another metal plate (10Y) different in rigidity from the one metal plate, these metal plates can also be arranged side by side, thereby, to make the rigidity of the metal mask partially different. Specifically, combining one metal plate (10X) including a metal material higher in rigidity and another metal plate (10Y) including a metal material lower in rigidity than the metal material included in the one metal plate (10X), the other metal plate (10Y) can also be arranged at a place where the rigidity of the metal mask 10 is desired to be reduced, thereby, to partially reduce the rigidity of the metal mask 10. In this case, the other metal plate (10Y) lower in rigidity functions as the rigidity adjustment part 35.

Moreover, a vapor deposition mask in a mode in which the vapor deposition mask 100 of the present disclosure described above, the vapor deposition mask 100 according to another embodiment (i), and the vapor deposition mask 100 according to another embodiment (ii) are properly combined can also be set.

(Frame-Equipped Vapor Deposition Mask)

A frame-equipped vapor deposition mask 200 of the present disclosure exhibits a configuration in which the vapor deposition mask 100 in each of the various modes described above is fixed to a frame 60.

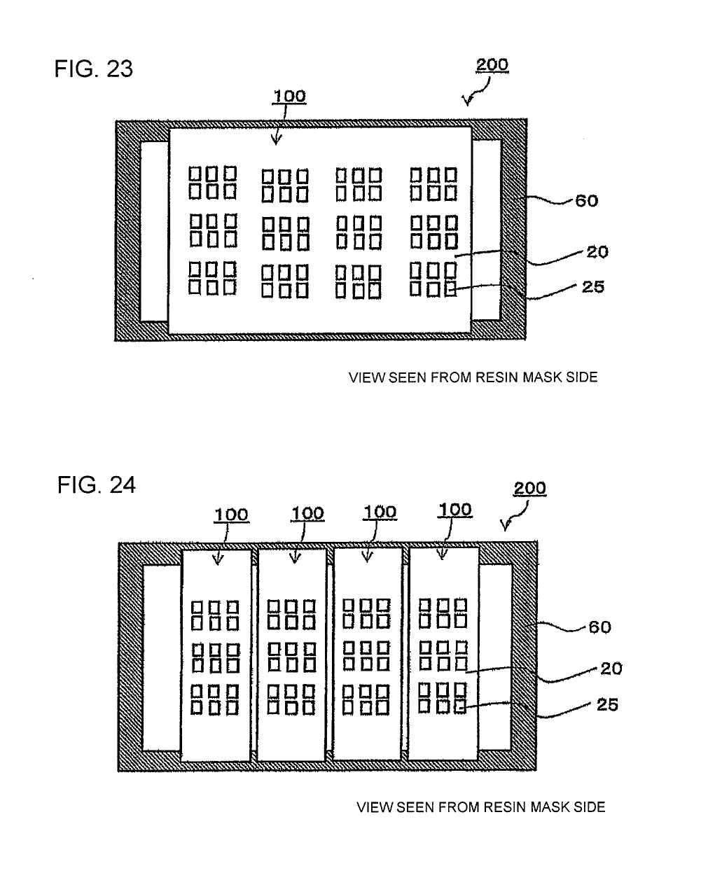

In the frame-equipped vapor deposition mask 200, one vapor deposition mask 100 may be fixed to the frame 60 as shown in FIG. 23, or a plurality of vapor deposition masks 100 may be fixed to the frame 60 as shown in FIG. 24.

The frame 60 is a substantially rectangular frame member and includes a through hole for exposing, to the vapor deposition source side, the resin mask openings 25 provided in the resin mask 20 of the vapor deposition mask 100 to be fixed in the final stage. As the material of the frame, a metal material, a glass material, a ceramic material and the like can be cited.

The thickness of the frame is not specially limited but is preferably within a range not less than about 10 mm and not more than about 30 mm in view of its rigidity and the like. The width between the inner circumferential end face of the opening of the frame and the outer circumferential end face of the frame is not specially limited as long as it is a width at which the metal mask of the vapor deposition mask can be fixed to the frame, but, for example, is within a range not less than about 10 mm and not more than about 70 mm.

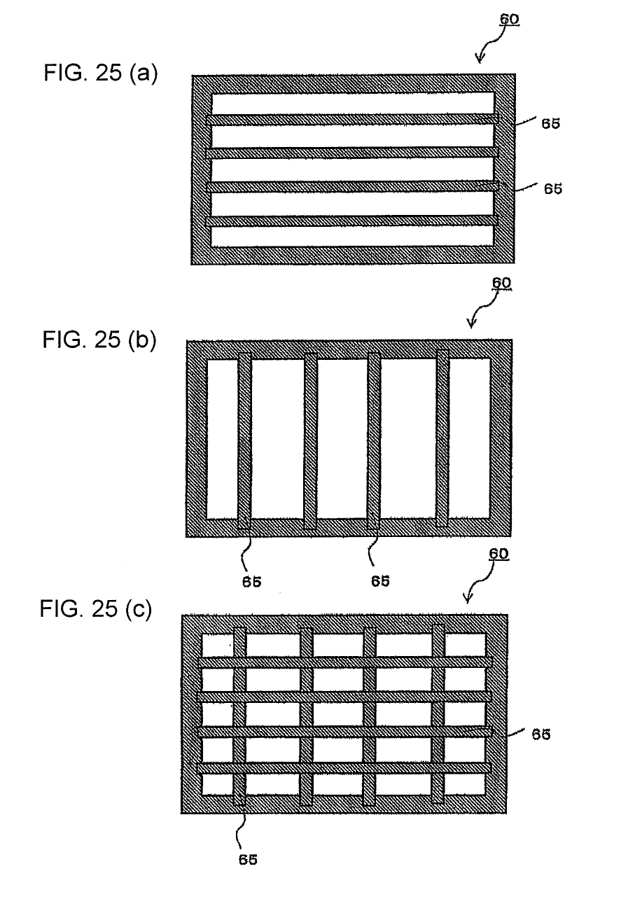

Moreover, as shown in FIGS. 25(a) to 25(c), the frame 60 in which reinforcement frames 65 and the like are provided in the region of the through hole of the frame may be used. In other words, a configuration in which the opening included in the frame 60 is divided by the reinforcement frames and the like may be included. To provide the reinforcement frames 65 also enables the frame 60 and the vapor deposition mask 100 to be fixed to each other using the reinforcement frames 65. Specifically, when a plurality of vapor deposition masks 100 described above are arranged and fixed in the lengthwise direction and the crosswise direction, the vapor deposition mask 100 can be fixed to the frame 60 also at positions where the reinforcement frames and the vapor deposition masks overlap with each other.

(Vapor Deposition Method Using Vapor Deposition Mask)

A vapor deposition method used for forming a vapor deposition pattern using the vapor deposition mask of the present disclosure is not specially limited but, for example, physical vapor deposition (PVD) methods such as a reactive sputtering method, a vacuum vapor deposition method, ion plating, and an electron beam vapor deposition method, chemical vapor deposition (CVD) methods such as thermal CVD, plasma CVD and photo-CVD methods, and the like can be cited. Moreover, a vapor deposition pattern can be formed using a conventionally known vacuum vapor deposition apparatus or the like.

<<Method for Producing Organic Semiconductor Element>>

Next, a method for producing an organic semiconductor element according to an embodiment of the present disclosure (hereinafter referred to as the method for producing an organic semiconductor element of the present disclosure) is described. The method for producing an organic semiconductor element of the present disclosure includes a step of forming a vapor deposition pattern on a vapor deposition target using a vapor deposition mask, wherein in the step of forming the vapor deposition pattern, the vapor deposition mask of the present disclosure described above is used.

Steps of forming a vapor deposition pattern by a vapor deposition method using the vapor deposition mask are not specially limited but include an electrode forming step, an organic layer forming step, a counter electrode forming step, a sealing layer forming step and the like in which electrodes are formed on a substrate, and in any of the steps, the vapor deposition pattern is formed using the vapor deposition pattern forming method of the present disclosure described above. For example, in the case where the step of forming a vapor deposition pattern of the present disclosure described above is applied to each of light-emitting layer forming steps for colors of R (red), G (green) and B (blue) in an organic EL device, vapor deposition patterns are formed for light-emitting layers for the colors on the substrate. Notably, the method for producing an organic semiconductor element of the present disclosure is not limited to be applied to these steps, but to any steps in conventionally known production of an organic semiconductor element.

According to the method for producing an organic semiconductor element of the present disclosure described above, vapor deposition for forming an organic semiconductor element can be performed in the state where the vapor deposition mask is brought into close contact with a vapor deposition target without a gap, and an organic semiconductor element with high definition can be produced. As organic semiconductor elements produced by the method for producing an organic semiconductor element of the present disclosure, for example, organic layers, light-emitting layers, cathode electrodes and the like of organic EL elements can be cited. In particular, the method for producing an organic semiconductor element of the present disclosure can be preferably used for production of R (red), G (green) and B (blue) light-emitting layers of organic EL devices which require pattern precision with high definition.

«Method for Producing Organic EL Display»

Next, a method for producing an organic EL display (organic electroluminescence display) according to an embodiment of the present disclosure (hereinafter referred to as method for producing an organic EL display according to the present disclosure) is described. In the method for producing an organic EL display according to the present disclosure, the organic semiconductor element produced by the method for producing an organic semiconductor element according to the present disclosure described above is used in a step of producing the organic EL display.

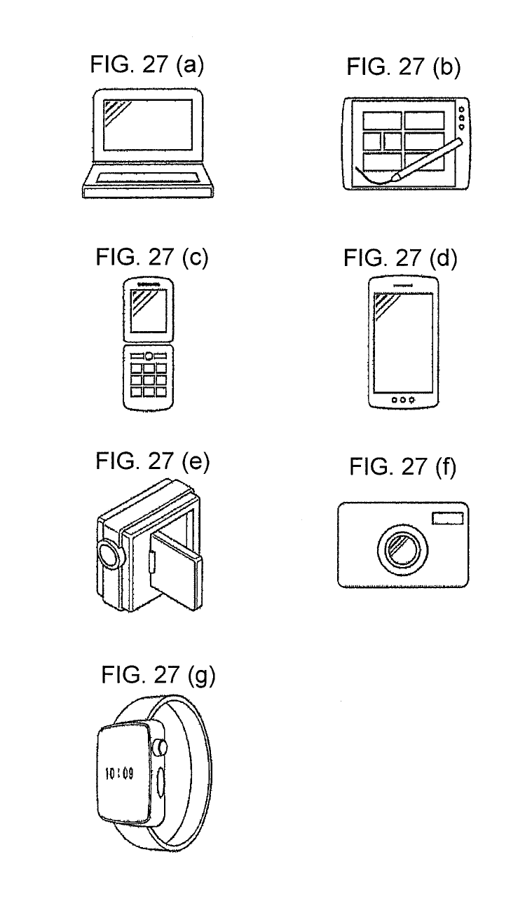

As the organic EL displays in which the organic semiconductor elements produced by the aforementioned method for producing an organic semiconductor element according to the present disclosure are used, for example, organic EL displays used for a notebook-sized personal computer (refer to FIG. 27(a)), a tablet terminal (refer to FIG. 27(b)), a mobile phone (refer to FIG. 27(c)), a smartphone (refer to FIG. 27(d)), a video camera (refer to FIG. 27(e)), a digital camera (refer to FIG. 28(f)), a smartwatch (refer to FIG. 28(g)) and the like can be cited.

### REFERENCE SIGNS LIST

10 Metal mask
15 Metal mask opening
25 Resin mask
20 Resin mask opening
30 Rigidity adjustment part arrangement region
35 Rigidity adjustment part
40 Through hole
45 Recess part
60 Frame
100 Vapor deposition mask

1. A vapor deposition mask comprising: a resin mask including a plurality of resin mask openings corresponding to a pattern to be produced by vapor deposition; and a metal mask including a metal mask opening, the resin mask and the metal mask being stacked such that the resin mask openings overlap with the metal mask opening, wherein
the metal mask includes one or a plurality of rigidity adjustment parts that partially reduce rigidity of the metal mask at a position not overlapping with the resin mask openings of the resin mask.

2. The vapor deposition mask according to claim 1, wherein the rigidity adjustment part is a through hole penetrating the metal mask or a recess part provided in the metal mask.

3. The vapor deposition mask according to claim 2, wherein when an area of a metal mask effective region as the metal mask that is assumed not to include the rigidity adjustment part is seen from the metal mask side in plan view is 100%, a total area of an opening region of the rigidity adjustment part as the vapor deposition mask is seen from the metal mask side in plan view is not less than about 3%.

4. The vapor deposition mask according to claim 2, wherein an opening area of one rigidity adjustment part is smaller than an opening area of one metal mask opening.

5. The vapor deposition mask according to claim 2, wherein an opening width of one rigidity adjustment part is smaller than an opening width of one metal mask opening.

6. The vapor deposition mask according to claim 2, wherein the rigidity adjustment part is positioned so as to enclose the metal mask opening as the vapor deposition mask is seen from the metal mask side in plan view.

7. The vapor deposition mask according to claim 2, wherein
a plurality of the metal mask openings are provided, and
the rigidity adjustment part is positioned between any adjacent pair of the metal mask openings as the vapor deposition mask is seen from the metal mask side in plan view.

8. The vapor deposition mask according to claim 1, wherein a thickness of the metal mask is within a range not less than about 5 μm and not more than about 35 μm.

9. The vapor deposition mask according to claim 1, wherein a sectional shape of the metal mask is a shape including broadening toward a vapor deposition source side.

10. The vapor deposition mask according to claim 1, wherein a thickness of the resin mask is within a range not less than about 3 μm and less than about 10 μm.

11. The vapor deposition mask according to claim 1, wherein a sectional shape of the resin mask is a shape including broadening toward a vapor deposition source side.

12. The vapor deposition mask according to claim 1, wherein a sectional shape of the resin mask is a curved shape convex outward.

13. The vapor deposition mask according to claim 1, wherein a thermal expansion coefficient of the resin mask is not more than about 16 ppm/° C.

14. The vapor deposition mask according to claim 1, wherein an opening space of the metal mask opening is partitioned by a bridge.

15. A vapor deposition mask comprising: a resin mask including a plurality of resin mask openings corresponding to a pattern to be produced by vapor deposition; and a metal mask including a metal mask opening, the resin mask and the metal mask being stacked such that the resin mask openings overlap with the metal mask opening, wherein
the metal mask includes one or a plurality of rigidity adjustment parts which partially enhance rigidity of the metal mask at a position not overlapping with the resin mask openings of the resin mask, and
the rigidity adjustment part is a metal reinforcement article provided on a surface, of the metal mask, that is not in contact with the resin mask.

16. A frame-equipped vapor deposition mask in which a vapor deposition mask is fixed to a frame, wherein
the vapor deposition mask is the vapor deposition mask according to claim 1.

17. The frame-equipped vapor deposition mask according to claim 16, wherein a plurality of the vapor deposition masks are fixed to the frame.

18. A method for producing an organic semiconductor element, comprising
a vapor deposition pattern forming step of forming a vapor deposition pattern on a vapor deposition target using a vapor deposition mask, wherein
the vapor deposition mask used in the vapor deposition pattern forming step is the vapor deposition mask according to claim 1.

19. A method for producing an organic EL display, wherein an organic semiconductor element produced by the method for producing an organic semiconductor element according to claim 18 is used.
